(19) United States
(12) Patent Application Publication
(10) Pub. No.: US 2001/0032987 A1
(43) Pub. Date: Oct. 25, 2001

(54) Image sensor, method of fabricating the same, and exposure apparatus, measuring device, alignment device, and aberration measuring device using the image sensor

(76) Inventors: Tadashi Narui, Kawasaki-shi (JP); Keiichi Akagawa, Kamakura-shi (JP)

Correspondence Address: Peter S. Gilster, Greensfelder, Hemker, & Gale, P.C., Intellectual Property Group, 10 South Broadway, Suite 2000, St. Louis, MO, 63102-1774, US

(21) Appl. No.: 09/810,227

(22) Filed: Mar. 16, 2001

(30) Foreign Application Priority Data
Mar. 17, 2000 (JP) 2000-076424
Aug. 29, 2000 (JP) 2000-259349
Nov. 29, 2000 (JP) 2000-363352
Feb. 23, 2001 (JP) 2001-048804
Feb. 23, 2001 (JP) 2001-048805

(51) Int. Cl. H01L 27/148

(52) U.S. Cl. 257/225

(57) ABSTRACT

In the present invention, a charge transfer unit is arranged on a first-plane side of a thinly-formed semiconductor base. Charge accumulating units are arranged on a second-plane side, the opposite side. A depletion prevention layer is arranged closer to the second-plane side than the charge accumulating units. The depletion prevention layer prevents a depletion region around the charge accumulating units from reaching the second plane of the semiconductor base. The depletion prevention layer can suppress surface dark current going into the charge accumulating units. Meanwhile, an energy ray incident from the second-plane side pass through the depletion prevention layer to generate signal charges in the charge accumulating units (depletion regions). The charge accumulating units collect, on a pixel-by-pixel basis, the signal charges which are to be transported to the charge transfer unit under voltage control or the like, and then are read to exterior as image signals.

### CROSS REFERENCE TO RELATED APPLICATION

The disclosure of the following priority application is herein incorporated by reference:

Japanese Patent Application No. 2000-076424, filed Mar. 17, 2000.

Japanese Patent Application No. 2000-259349, filed Aug. 29, 2000.

Japanese Patent Application No. 2000-363352, filed Nov. 29, 2000.

Japanese Patent Application No. 2001-048804, filed Feb. 23, 2001.

Japanese Patent Application No. 2001-048805, filed Feb. 23, 2001.

### BACKGROUND OF THE INVENTION

1. Field of the Invention

The present invention relates to a back-illuminated image sensor wherein energy rays (visible light, ultraviolet rays, soft X-rays, electron beams, and so on) are received at one plane side of a semiconductor (second-plane side) and optoelectronically converted signal charges are transported to a charge transfer unit on the other plane side (first-plane side) for readout.

The present invention relates to a method of fabricating the image sensor.

The present invention relates to a method of fabricating a device such as the image sensor where alignment of its double-sided structure is required.

The present invention relates to a measuring device, exposure apparatus, alignment device, and aberration measuring device which comprise the image sensor.

2. Description of the Related Art

FIG. 36 is a diagram showing a conventional back-illuminated image sensor 601.

In FIG. 36, a semiconductor base 602 consisting of a P-type epitaxial layer is formed in a thickness of the order of 10 μm. An N-type CCD diffusion layer 603 is formed in the first-plane side of the semiconductor base 602 for the sake of charge transfer. The CCD diffusion layer 603 has a plurality of transfer electrodes 605 arranged thereon across a gate oxide film 604. The semiconductor base 602 is provided with an antireflection film 609, a support substrate 611, and so on.

The image sensor 601 configured thus is illuminated at its second-plane side with energy rays. The energy rays produce electron-hole pairs on the second-plane side of the semiconductor base 602. Some of the electrons travel through the semiconductor base 602 until they reach a potential well of the CCD diffusion layer 603 and are accumulated as a signal charge.

The signal charge in the CCD diffusion layer 603 is transferred by applying voltages to the transfer electrodes 605, and is successively read out to exterior.

In such a back-illuminated image sensor 601, the electrons produced at the second-plane side travel through the semiconductor base 602. Accordingly, there has been a problem that the electrons tend to recombine with holes and disappear, with a low efficiency of energy ray detection.

There has been another problem that the electrons traveling through the semiconductor base 602 get mixed between pixels, and thereby cause smear. The smear increases with a decreasing pixel pitch of the image sensor. On that account, the smear production makes it extremely difficult to improve the image sensor in resolution.

In particular, energy rays of shorter wavelengths, such as ultraviolet rays, produce electron-hole pairs at very shallow depth in the second-plane side. Therefore, in the cases of short-wavelength energy rays, the above-mentioned two problems tend to be more significant since electrons have particularly longer traveling distances.

Meanwhile, there has been another problem that the characteristics of the image sensor 601 largely depend on the impurity concentration and thickness of the semiconductor base 602. For example, when the semiconductor base 602 varies in impurity concentration and thickness at the time of manufacturing, the frequency of the electron-hole recombination varies from one product to another, resulting in varying efficiency of the energy ray detection. Additionally, the degree of mixing of electrons between adjoining pixels also varies from one product to another, so that smear occurs in different degrees. Such product variations have been a major cause for the image sensor 601 to drop in production yield.

Furthermore, in the conventional image sensor 601, electrons continually flow in from the second-plane side even while the signal charge is being transferred. This has required that the second-plane side be completely shielded from light during charge transfer. Thus, there has been a problem that the conventional image sensor 601 requires a mechanical shutter, which complicates the peripheral mechanisms of the image sensor.

In addition, the conventional image sensor 601 has had a problem that many dark current arise at the interface between the antireflection film 609 and the semiconductor base 602, and at the interface between the gate oxide film 604 and the CCD diffusion layer 603. Such dark current have caused unwanted effects including a deterioration in imaging quality and the impossibility of weak light detection.

Moreover, in the conventional image sensor 601, the surface state and trapped charges create potential wells near the surface of the second plane (hereinafter, referred to as “backside wells”). The backside wells capture electrons and lower the efficiency of the energy ray detection.

By the way, for the sake of fabricating the conventional image sensor 601, it is required that the transfer electrodes 605 and others be formed from the first-plane side, and that holes intended for bonding pads be made from the second-plane side. Conventionally, the alignment of such double-sided structure is achieved by using special devices such as a double side aligner or an infrared aligner.

More specifically, in the cases of a double side aligner, a structure was formed on the second-plane side while the alignment was made to an alignment mark on the first-plane side.

In the cases of an infrared aligner, the alignment mark on the first-plane side was sensed through from the second-plane side by using an infrared ray. By using the perspective image of the alignment marks as an alignment reference, the structure on the second-plane side was formed.

Double side aligners, however, produce alignment errors of ±2 μm. Infrared aligners also produce alignment errors of ±3 μm.

The alignment errors are ascribable to the indirect use of the alignment mark on the opposite plane. Thus, it has been extremely difficult in principle to improve the precision of the alignment. Accordingly, there has been a problem that whichever aligner is used, double-sided structure cannot be aligned with precision.

### SUMMARY OF THE INVENTION

In view of the foregoing, an object of the present invention is to provide a back-illuminated image sensor with high efficiency of detecting energy ray, low smear production, and no need of having mechanical shutters.

Another object of the present invention is to provide a back-illuminated image sensor capable of suppressing dark current from the second-plane side.

Another object of the present invention is to provide a back-illuminated image sensor capable of suppressing dark current from the first-plane side.

Another object of the present invention is to provide a back-illuminated image sensor in which it is possible to reliably transfer a charge in a charge accumulating unit to a charge transfer unit.

Another object of the present invention is to provide a back-illuminated image sensor capable of improving driving speed in charge transportation.

Another object of the present invention is to provide a method of fabricating an image sensor according to the present invention.

Another object of the present invention is to provide an exposure apparatus incorporating an image sensor according to the present invention.

Another object of the present invention is to provide an alignment device incorporating an image sensor according to the present invention.

Another object of the present invention is to provide a measuring device incorporating an image sensor according to the present invention.

Another object of the present invention is to provide an aberration measuring device incorporating an image sensor according to the present invention.

Another object of the present invention is to provide a device fabrication method which is suitable for achieving strict alignment of double-sided structure as in an image sensor according to the present invention.

Another object of the present invention is to lessen the influences of impurity concentration rate or thickness of a semiconductor base.

Another object of the present invention is to provide an image sensor suited for higher resolution.

To achieve the foregoing objects, the present invention provides the following configurations.

An image sensor according to the present invention comprises: a semiconductor base of a first conductive type; a plurality of charge accumulating units of a second conductive type (a conductive type different from the first conductive type) formed on a second-plane side (the backside of a first plane) of the semiconductor base, for accumulating, on a pixel-by-pixel basis, signal charges generated by an energy ray incident from the second-plane side; a charge transfer unit formed on the first-plane side of the semiconductor base facing the charge accumulating units, for transferring the signal charges to be read; a charge transport unit for transporting the signal charges accumulated in the charge accumulating units to the charge transfer unit; and a depletion prevention layer formed closer to the second-plane side than the charge accumulating units, for preventing a depletion region around the charge accumulating units from reaching the second plane.

In the configuration described above, the charge accumulating units, or regions of the second conductive type are formed between the second plane and the charge transfer unit on a pixel-by-pixel basis. Charges in the charge accumulating units are discharged to the charge transfer unit or the like to form a potential well. The potential well (charge accumulating units) has the function of collecting, on a pixel-by-pixel basis, signal charges occurring on the second-plane side.

The traveling distance of charges on the second-plane side is reduced in accordance with the width of the potential well. Therefore, the charge recombination is suppressed by the amount of reduction, improving the efficiency of energy ray detection. In addition, a synergistic effect of the “reduction in traveling distance” and “the function of collecting signal charges into the charge accumulating units on a pixel-by-pixel basis” surely reduces the mix-up of signal charges between adjoining pixels. Thereby, the production of smear is suppressed.

Furthermore, in the above-described configuration, the charge accumulating units are arranged closer to the second-plane side than the charge transfer unit. Therefore, the flow of signal charges into the charge transfer unit can be intercepted. This eliminates the need for the second plane to be shielded from light during transfer of the signal charge by the charge transfer unit, allowing an omission of a mechanical shutter.

Moreover, in the above-described configuration, the charge accumulating units and the charge transfer unit are arranged in three dimensions in the direction of thickness of the semiconductor base. Therefore, as compared with an image sensor having the charge accumulating units and the charge transfer unit in a two-dimensional arrangement, it is easier to reduce the chip size or enlarge the photoreceptor area. The enlargement of photoreceptor area allows reliable improvement in the efficiency of energy ray detection.

In particular, the present invention provides a depletion prevention layer on the second-plane side of the charge accumulating units. The depletion prevention layer prevents a depletion region occurring at the charge accumulating units from reaching the interface of the second plane. For that reason, most of dark current randomly arising at the interface of the second plane is diffused and recombined to disappear in the depletion prevention layer before reaching the charge accumulating units. This makes it possible to obtain favorable images with less dark current.

Note that in the present invention, it is preferable that the depletion prevention layer has impurity distribution (impurity profiles, and more specifically concentration rate and thickness) that allows the energy ray to pass through, and an impurity concentration rate enough to prevent a depletion region from reaching the second plane. Due to the setting of the thickness of the depletion prevention layer, most energy rays pass through the depletion prevention layer and reach the depletion regions in the charge accumulating units. As a result, it enables efficient capture of signal charges in the charge accumulating units, thereby improving the efficiency of energy ray detection.

In the present invention, the depletion prevention layer is preferably of the first conductive type. The depletion prevention layer of the first conductive type can fill the backside wells described above. This is particularly effective for improving the efficiency of energy ray detection.

It is preferable in the present invention that the charge accumulating units are fully depleted at the completion of charge transportation. The full depletion can substantially reduce image lags. Incidentally, the depletion prevention layer has the function of facilitating the full depletion.

Meanwhile, another image sensor according to the present invention comprises: a semiconductor base of a first conductive type; a plurality of charge accumulating units of a second conductive type (a conductive type different from the first conductive type) formed on a second-plane side (the backside of a first plane) of the semiconductor base, for accumulating, on a pixel-by-pixel basis, signal charges generated by an energy ray incident from the second-plane side; a charge transfer unit formed on the first-plane side of the semiconductor base facing the charge accumulating units, for transferring the signal charges to be read; a charge transport unit for transporting the signal charges accumulated in the charge accumulating units to the charge transfer unit; and an invalid charge discharging unit for driving the charge transfer unit to discharge an invalid charge while the charge accumulating units accumulate the signal charges.

In the configuration described above, the invalid charge discharging unit sweeps invalid charges out of the charge transfer unit while the charge accumulating units accumulate signal charges. This eliminates a possibility of residence of dark current arising on the first-plane side of the charge transfer unit, thereby realizing an image sensor with less occurrence of dark current.

In this connection, the invalid charge discharging unit may drive the charge transport unit and the charge transfer unit to transport and discharge the invalid charges in the charge accumulating units at appropriate timing. In this case, the accumulating time of the signal charges in the charge accumulating units (i.e., exposure time) becomes adjustable, which realizes an electronic shutter function.

Another image sensor according to the present invention comprises: a semiconductor base of a first conductive type; a plurality of charge accumulating units of a second conductive type (a conductive type different from the first conductive type) formed on a second-plane side (the backside of a first plane) of the semiconductor base, for accumulating, on a pixel-by-pixel basis, signal charges generated by an energy ray incident from the second-plane side; a charge transfer unit formed on the first-plane side of the semiconductor base facing the charge accumulating units, for transferring the signal charges to be read; a charge transport unit for transporting the signal charges accumulated in the charge accumulating units to the charge transfer unit; and a dark current suppressing unit for approximating the potential of the first-plane side of the charge transfer unit to a substrate potential to suppress a dark current flowing in from the first-plane side, at least for a predetermined period while the charge accumulating units accumulate the signal charges.

In the configuration described above, the dark current suppressing unit manipulate the potential of the first-plane side of the charge transfer unit so as to be brought closer to the substrate potential. Such a potential manipulation avoids the surface depletion of the first-plane side, and thereby reduces a possibility of dark current on the first-plane side going into the charge transfer unit.

Another image sensor according to the present invention comprises: a semiconductor base of a first conductive type; a plurality of charge accumulating units of a second conductive type (a conductive type different from the first conductive type) formed on a second-plane side (the backside of a first plane) of the semiconductor base, for accumulating, on a pixel-by-pixel basis, signal charges generated by an energy ray incident from the second-plane side; a charge transfer unit formed on the first-plane side of the semiconductor base facing the charge accumulating units, for transferring the signal charges to be read; a charge transport unit for transporting the signal charges accumulated in the charge accumulating units to the charge transfer unit; and an excessive charge discharging unit for overflowing an excessive charge into the charge transfer unit and driving the charge transfer unit to discharge the excessive charge, the excessive charge occurring due to exceeding a saturation charge amount of the charge accumulating units.

In the configuration described above, the excessive charge discharging unit discharges excessive charges overflowing from the charge accumulating units, through the charge transfer unit. This reduces a possibility of excessive charges overflowing into the charge accumulating units of adjacent pixels; therefore, it becomes possible to suppress blooming phenomena with reliability.

Another image sensor according to the present invention comprises: a semiconductor base of a first conductive type; a plurality of charge accumulating units of a second conductive type (a conductive type different from the first conductive type) formed on a second-plane side (the backside of a first plane) of the semiconductor base, for accumulating, on a pixel-by-pixel basis, signal charges generated by an energy ray incident from the second-plane side; a charge transfer unit formed on the first-plane side of the semiconductor base facing the charge accumulating units, for transferring the signal charges to be read; and a charge transport unit for transporting the signal charges accumulated in the charge accumulating units to the charge transfer unit. Here, the charge transport unit applies a voltage to the semiconductor base to control the charge accumulating units in potential, thereby transporting the charges in the charge accumulating units to the charge transfer unit.

In the configuration described above, the substrate potential of the semiconductor base is directly manipulated to transport the signal charges from the charge accumulating units to the charge transfer unit. Therefore, it is possible to facilitate the control of full depletion of the charge accumulating units, thereby further ensuring transporting operation of signal charges. The results in less possibilities of causing image lag phenomena due to signal charges left in the charge accumulating units. In addition, it is possible to sufficiently adapt to charge accumulating units with a greater saturation charge amount.

In the present invention, the semiconductor base preferably has a well structure surrounded by a semiconductor region of the second conductive type. In such a configuration, the well structure electrically isolates the semiconductor base from its surroundings. This means not much increase in the size of the semiconductor base, allowing an appropriate reduction in the electrical capacitance of the semiconductor base. Thus, upon a voltage application to the semiconductor base, the substrate potential can be controlled at high speed, permitting a further speedup of the transporting operation from the charge accumulating units to the charge transfer unit.

Meanwhile, a fabrication method according to the present invention comprises the steps of: thinning a semiconductor base of a first conductive type; forming, on one plane side of the semiconductor base thinned, a plurality of charge accumulating units of a second conductive type different from the first conductive type; and forming, on the one plane side of the semiconductor base thinned, a depletion prevention layer of the first conductive type for preventing a surface deletion resulting from the charge accumulating units.

In the fabrication method described above, since both the charge accumulating units and the depletion prevention layer are formed from the second-plane side, the charge accumulating units can be precisely controlled in surface depth. Accordingly, the surface depth of the charge accumulating units can be formed as shallow as possible in order to further facilitate an improvement in the efficiency of detection of short-wavelength energy rays. In addition, forming the depletion prevention layer from the second-plane side stabilizes the depletion prevention layer in thickness and impurity concentration, which permits the fabrication of a back-illuminated image sensor having even less dark current.

Another image sensor according to the present invention comprises: a semiconductor base of a first conductive type; a plurality of charge accumulating units of a second conductive type (a conductive type different from the first conductive type) formed on a second-plane side (the backside of a first plane) of the semiconductor base, for accumulating, on a pixel-by-pixel basis, signal charges generated by an energy ray incident from the second-plane side; a charge transfer unit formed on the first-plane side of the semiconductor base facing the charge accumulating units, for transferring the signal charges to be read; a charge transport unit for transporting the signal charges accumulated in the charge accumulating units to the charge transfer unit; and a barrier region arranged on at least a part of transport paths of the signal charges formed between the charge accumulating units and the charge transfer unit, the barrier region creating a peak of a potential barrier to block progress of the signal charges when no charge is to be transported, the peak of the potential barrier being eliminated by the charge transport unit to ensure full transportation of the signal charges when charges are transported.

In the configuration described above, the barrier region is formed between the charge accumulating units and the charge transfer unit. The peak of the potential barrier occurring in the barrier region makes it possible to control the threshold conditions for the charge transportation. Therefore, even when the semiconductor base has production variations, the threshold conditions for the charge transportation will not substantially vary.

In addition, in the above-described configuration, the signal charges are once collected to the charge accumulating units on a pixel-by-pixel basis. This reduces the frequency of signal charges between adjoining pixels mixed with each other in the semiconductor base. Therefore, even when the semiconductor base has production variations, the degree of smear production will not substantially vary.

The above functions and effects make it possible to reduce influences on the characteristics of the back-illuminated image sensor due to production variations of the semiconductor base. As a result, the image sensor can be improved in production yield.

Furthermore, in the above-described configuration, the charge accumulating units and the charge transfer unit can be distinctively separated by the peak of the potential barrier arising in the barrier region. In this case, the possibility of charges going into the charge transfer unit during charge transfer becomes even smaller. This leads to scarcely causing unwanted effects resulted from charge intrusion without having a mechanical shutter.

In the present invention, the barrier region is preferably formed by introducing impurities of the first conductive type into the semiconductor base. Moreover, in the present invention, the impurities introduced into the barrier region are preferably set to be higher in concentration rate than that of the semiconductor base. In such a configuration, the impurity concentration rate of the semiconductor base can be previously set at a lower value so that additional impurities are introduced to the semiconductor base to form the barrier region. In this case, the lower impurity concentration rate of the semiconductor base significantly reduces such production defects as “uneven transportation of signal charges” and “the production of defective pixels” because of unevenness and variations in the fabrication conditions of the semiconductor base. This allows a further improvement in the production yield of the back-illuminated image sensor.

In the present invention, the barrier region is preferably arranged in contact with the charge transfer unit. In such a configuration, it is possible to exercise reliable and precise potential control of the peak of the potential barrier from the charge-transfer-unit side (for example, the transfer electrodes arranged on the charge transfer unit).

In the present invention, the barrier region is preferably set so that the potential barrier, when no charge is to be transported, is lower than potential barriers between adjoining charge accumulating units according to the viewpoint of the polarity of the signal charges. In such a configuration, the charge transfer unit can be operated as an overflow drain. More specifically, signal charges overflowing the charge accumulating units because of an excessive exposure (hereinafter, referred to as “excessive charges”) overcome the barrier region to flow to the charge transfer unit before overcoming the higher potential barriers between the adjoining charge accumulating units. This makes it possible to improve the blooming between adjacent pixels (blurs due to excessive charges in the sensed image). Here, it is also preferable that the charge transfer unit performs the charge transfer of the excessive charges. The operation prevents excessive charges from residing in the charge transfer unit, thereby allowing immediate transfer (i.e., discharge) of the same.

Meanwhile, another fabrication method according to the present invention comprises the steps of: forming an epitaxial layer of a first conductive type on a first-plane side of a substrate; introducing impurities of the first conductive type into the epitaxial layer from the first-plane side to form a barrier region; introducing impurities of a second conductive type different from the first conductive type into the epitaxial layer so as to form a charge transfer unit in the first-plane side at a region located shallower than the barrier region as seen from the first-plane side; removing at least a part of the substrate to thin a second-plane side opposite to the first-plane side; and introducing impurities of the second conductive type from the second-plane side so as to form charge accumulating units in a pixel-by-pixel arrangement. The fabrication method makes it possible to surely fabricate a back-illuminated image sensor having charge accumulating units and a barrier unit.

Another fabrication method according to the present invention comprises the steps of: forming a first epitaxial layer of a first conductive type on a first-plane side of a substrate; introducing impurities of a second conductive type different from the first conductive type into the first epitaxial layer from the first-plane side so as to form charge accumulating units in a pixel-by-pixel arrangement; introducing impurities of the first conductive type into the first-plane side of the first epitaxial layer at a region located shallower than the charge accumulating units as seen from the first-plane side, thereby forming a barrier region; forming a second epitaxial layer of the first conductive type on the first-plane side of the first epitaxial layer; introducing impurities of the second conductive type into the first-plane side of the second epitaxial layer to form a charge transfer unit; and removing at least a part of the substrate to thin a second-plane side opposite to the first-plane side. The fabrication method also makes it possible to surely fabricate a back-illuminated image sensor having charge accumulating units and a barrier region.

Another fabrication method according to the present invention comprises the steps of: forming a first epitaxial layer of a first conductive type on a first-plane side of a substrate; introducing impurities of a second conductive type different from the first conductive type into the first epitaxial layer from the first-plane side so that charge accumulating units are formed in a pixel-by-pixel arrangement; forming a second epitaxial layer of the first conductive type on the first-plane side of the first epitaxial layer; introducing impurities of the first conductive type into the first-plane side of the second epitaxial layer to form a barrier region; introducing impurities of the second conductive type into the first-plane side of the second epitaxial layer at a region shallower than the charge accumulating units as seen from the first-plane side, thereby forming a charge transfer unit; and removing at least a part of the substrate to thin a second-plane side opposite to the first-plane side. The fabrication method also makes it possible to surely fabricate a back-illuminated image sensor having charge accumulating units and a barrier region.

Another image sensor according to the present invention comprises: a semiconductor base of a first conductive type; charge accumulating units of a second conductive type arranged on a second-plane side of the semiconductor base, for accumulating, on a pixel-to-pixel basis, signal charges generated by an energy ray incident from the second-plane side; a charge transfer channel formed on the first-plane side of the semiconductor base facing the charge accumulating units, the signal charges being transferred and read out through the charge transfer channel; and transfer electrodes for applying a transfer voltage to the charge transfer channel. The transfer electrodes are periodically provided in the charge transfer direction of the charge transfer channel, in proportion of substantially two or less transfer electrodes per one charge accumulating unit. In the present invention, it is preferable that the transfer electrodes are periodically provided in the charge transfer direction of the charge transfer channel, in proportions of substantially two to a single piece of the charge accumulating units.

In such a configuration, one charge accumulating unit is substantially provided facing two transfer electrodes or less. Here, the charge accumulating units can be arranged closer to each other as compared with the case where one charge accumulating unit is arranged in every phase interval (equivalent to three to four transfer electrodes, generally). This facilitates back-illuminated image sensors of higher resolution. Moreover, in this case, the signal charges are once collected to the charge accumulating units on a pixel-by-pixel basis. Therefore, the frequency of signal charges of adjoining pixels getting mixed with each other in the semiconductor base, can be reduced, thereby lessening influences of the production variations of the semiconductor base on the smear production.

In the present invention, it is preferable to provide a split transport unit for transporting signal charges from the charge accumulating units to the charge transfer channel, the transporting being performed at phase intervals of the transfer electrodes (the intervals of the transfer electrodes to which identical voltage waveforms are applied during multi-phase drive), and for transporting one screenful of signal charges at a plurality of times while shifting the phases of positions where signal charges are to be transported; and a split transfer unit for driving the transfer electrodes in multi-phase, each time the split transport unit transports signal charges to the charge transfer channel, so that one screenful of signal charges are read out at a plurality of times. In such a configuration, the signal charges are transferred to the charge transfer unit from the charge accumulating units, which is performed at phase intervals. The smear production can be further reduced by not transferring the signal charges at once but transferring them with intervals.

In the present invention, the charge transfer channel may have variations in impurity concentration “in every interval of the transfer electrodes,” so that the transfer electrodes are driven in two phases to transfer signal charges progressively. In such a configuration, the variations in impurity concentration create periodic potential gradients in the charge transfer channel, which allows one-way transfer of the signal charges with reliability.

Meanwhile, an alignment device according to the present invention comprises: an image sensor of the present invention described above; a position detecting unit for detecting positional information of the subject according to the image sensed of an object or a mark formed on the object by using the image sensor; and a position controlling unit for positioning the object according to the positional information. In such a configuration, the use of the image sensor of the present invention described above offers various improvements and effects including a higher efficiency in energy ray detection and a decrease in the smear production. Therefore, the sensed images increase in image quality, improving the detection of positional information in accuracy. As a result, the alignment device according to the present invention can realize a further improvement in object positioning accuracy.

An exposure apparatus according to the present invention comprises: an image sensor of the present invention described above; and an exposure unit for exposing a predetermined pattern onto a substrate positioned by the alignment device. In such a configuration, the use of the alignment device of the present invention described above allows an improvement in substrate positioning accuracy. Therefore, the exposure apparatus according to the present invention can make a further improvement in the positional accuracy of exposure on a substrate.

An aberration measuring device according to the present invention comprises: an image sensor of the present invention described above; an aberration measuring optical system for emitting a pencil of light for aberration measurement into an optical system to be measured; a condenser lens for condensing the pencil of light to pass through the optical system to be measured onto an imaging plane of the image sensor; a position detecting unit for detecting positional information of the pencil of light condensed on the imaging plane; and an operation unit for determining an aberration of the optical system to be measured, according to the detection result from the position detecting unit. In such a configuration, the use of the image sensor of the present invention described above offers various improvements and effects including a higher efficiency in energy ray detection and a decrease in the smear production. Therefore, the sensed images increase in image quality, allowing a further improvement in aberration measurement accuracy.

Another exposure apparatus according to the present invention comprises: the aberration measuring device of the present invention described above; and a projection optical system to be subjected to the aberration measurement by the aberration measuring device. In such a configuration, the use of the aberration measurement device of the present invention makes it possible to precisely measure the projection optical system for aberration. Therefore, the exposure apparatus according to the present invention can correct the aberration of the projection optical system with yet higher precision, allowing finer exposure patterns to be precisely projected.

A measuring device according to the present invention comprises: an image sensor of the present invention described above; and a measuring unit for performing at least one of aberration measurement and position measurement of a subject, according to an image of the subject sensed by the image sensor. In such a configuration, the use of the image sensor of the present invention described above offers various improvements and effects including a higher efficiency in energy ray detection and a decrease in the smear production. This makes it possible to obtain favorable sensed images with smaller variations, so that the aberration measurement or the position measurement of the subject can be performed with a higher degree of accuracy.

Another exposure apparatus according to the present invention comprises: an exposure unit for projecting an exposure pattern onto an object to be exposed; the above-described measuring device of the present invention; and a control unit for performing at least one of aberration correction on the exposure unit and positional control of an exposure position, according to a measurement output from the measuring unit. In such a configuration, the use of the measuring device of the present invention makes it possible to obtain aberration measurements or position measurements with a higher degree of accuracy. As a result, the exposure apparatus can perform the aberration correction of the exposure unit or the positioning of the exposure pattern with high precision.

Next, description will be given of the device fabrication methods according to the present invention. Incidentally, as employed in the present invention, the expression “with something as a (positional) reference” implies “with a history of something or a re-formed mark as a (positional) reference.”

A device fabrication method according to the present invention comprises the steps of: forming a first alignment mark on a first-plane side of a substrate; forming a base portion of a device on the first-plane side of the substrate; forming a predetermined structure on the first-plane side of the base portion, with “a projection or a depression on the first-plane side of the base portion”, as a positional reference, occurring due to the projection or depression of the first alignment mark in the process of forming the base portion; removing the substrate from a second-plane side of the base portion, or the opposite side of the first-plane side; and forming a predetermined structure on the second-plane side of the base portion, with a second alignment mark (the inverted mark of the first alignment mark), as a positional reference, appearing on the second-plane side of the base portion due to the removing process.

In the device fabrication method, the first alignment mark is formed on the first-plane side of the substrate, and then the base portion of the device is formed thereon. Here, the projection/depression of the first alignment mark appears on the first-plane side of the base portion as a trace of the projection/depression (hereinafter, referred to as “history”). The history is in alignment with the first alignment mark. The use of the history as a positional reference allows a device structure in alignment with the first alignment mark to be formed on the first-plane side of the base portion.

Subsequently, the substrate is removed from the second-plane side of the base portion. Here, on the second-plane side of the base portion, the second alignment mark appears as a trace of the first alignment mark removed. The second alignment mark is in alignment with the first alignment mark. The use of the second alignment mark as a positional reference allows a device structure in alignment with the first alignment mark to be formed on the second-plane side of the base portion.

As described above, device structures in alignment with the first alignment mark are formed on both the first- and second-plane sides. Therefore, it becomes possible to fabricate a device with double-sided structure in precise alignment.

Moreover, in the device fabrication method described above, the device structure on either side is formed in accordance with the positional reference (the history, the second alignment mark) on that side. Accordingly, there is no need to use the alignment marks on the respective opposite sides as the positional references, so that the conventional double side aligners and infrared aligners are not particularly required. On that account, it is possible to fabricate a device where alignment of its double-sided structure is required, by employing common fabrication apparatus.

Another device fabrication method according to the present invention comprises the steps of: forming a base portion of a device on a first-plane side of a substrate; forming a to-be-removed region in the base portion, the to-be-removed region reaching the substrate and being selectively removable; forming a first alignment mark on the first-plane side in the to-be-removed region; forming a predetermined structure on the first-plane side of the base portion by using the first alignment mark as a positional reference; forming a layer to cover at least the first alignment mark; removing the substrate and the to-be-removed region from a second-plane side of the base portion, or the opposite side of the first-plane side; and forming a predetermined structure on the second-plane side of the base portion by using, as the positional reference, a second alignment mark (the inverted mark of the first alignment mark) appearing on the second-plane side in the process of removing the substrate.

In the device fabrication method, the base portion of a device is formed on the first-plane side of the substrate. During or after the forming process, a to-be-removed region that reaches the substrate is formed in the base portion. In addition, a first alignment mark is formed on the first-plane side of the to-be-removed region.

By using the first alignment mark as a positional reference, a device structure is formed on the first-plane side of the base portion. Therefore, the device structure formed on the first-plane side of the base portion is in alignment with the first alignment mark.

When a layer is formed to cover the first alignment mark during the process of forming the base portion or the device structure, that is considered the layer forming step. On the other hand, when such a layer is not formed otherwise, the layer forming step is performed separately.

By covering the first alignment mark thus, the substrate is removed from the second-plane side of the base portion. Here, the to-be-removed region is preferably removed together. If, however, the to-be-removed region is not removed together, it will be separately removed.

In the trace of the removed to-be-removed region appears the second alignment mark which is the first alignment mark inverted of projections/depressions. The second alignment mark is in alignment with the first alignment mark. Using the second alignment mark as a positional reference allows a device structure in alignment with the first alignment mark to be formed on the second-plane side of the base portion.

In this way, device structures in alignment with the first alignment mark are formed on both the first- and second-plane sides. Therefore, it is possible to fabricate a device with double-sided structure in precise alignment.

Moreover, in the device fabrication method described above, the device structure on either side is formed in accordance with the positional reference (the history, the second alignment mark) on that side. Accordingly, there is no need to use the alignment marks on the respective opposite sides as the positional references, so that the conventional double side aligners and infrared aligners are not particularly required. On that account, it is possible to fabricate a device where alignment of its double-sided structure is required, by employing common fabrication apparatus.

Another device fabrication method according to the present invention comprises the steps of: forming a first alignment mark on a first-plane side of a substrate; forming a base portion of a device on the first-plane side of the substrate; forming a second alignment mark (a re-formed mark of the first alignment mark) on the first-plane side of the base portion by using, as a positional reference, one of a projection and a depression on the first-plane side of the base portion, the projection or depression occurring due to a projection or a depression of the first alignment mark in the base forming step; and forming a predetermined structure on the first-plane side of the base portion by using the second alignment mark as a positional reference.

In the device fabrication method, the first alignment mark is formed on the first-plane side of the substrate, and then the base portion of the device is formed thereon. Here, the projection/depression of the first alignment mark appears as a history on the first-plane side of the base portion. The history is in alignment with the first alignment mark. Then, with the history as a positional reference, a re-formed mark is formed. The use of the re-formed mark as a positional reference allows a device structure in alignment with the first alignment mark to be formed on the first-plane side of the base portion.

Another device fabrication method according to the present invention comprises the steps of: forming a first alignment mark on a first-plane side of a substrate, the first alignment mark comprising one of a projection and a depression; forming a base portion of a device on the first-plane side of the substrate; removing the substrate from a second-plane side of the base portion, or the opposite side of the first-plane side, so that a second alignment mark (the inverted mark of the first alignment mark) appears on the second-plane side of the base portion; and forming a predetermined structure on the second-plane side of the base portion by using the second alignment mark as a positional reference.

In the device fabrication method, the first alignment mark is formed on the first-plane side of the substrate, and then the base portion of the device is formed thereon.

Thereafter, the substrate is removed. Upon the removal of the substrate, the second alignment mark, or the inverted mark of the first alignment mark, appears on the second-plane side of the base portion. By using the second alignment mark as a positional reference, a device structure is formed on the base portion.

The fabrication method makes it possible to form a device structure in alignment with the first alignment mark on the second-plane side of the base portion.

Another device fabrication method according to the present invention comprises the steps of: forming a base portion of a device on a first-plane side of a substrate; forming a to-be-removed region in the base portion, the to-be-removed region reaching the substrate and being selectively removable; forming a layer to cover at least the first alignment mark; removing the substrate and the to-be-removed region from a second-plane side of the base portion, or the opposite side of the first-plane side, so that a second alignment mark (a trace of the removed first alignment mark) appears on the second-plane side of the base portion; and forming a predetermined structure on the second-plane side of the base portion by using the second alignment mark as a positional reference.

In the device fabrication method, the base portion of a device is formed on the first-plane side of the substrate. During or after the forming process, the pattern of a to-be-removed region piercing through the substrate is formed on the base portion. The pattern is formed in accordance with the positional reference on the first-plane side. On that account, the pattern of the to-be-removed region naturally comes into alignment with the device structure on the first-plane side, which also uses the positional reference.

When a layer is formed to cover the to-be-removed region during the forming process of the base portion, this is considered the layer forming step. On the other hand, when such a layer is not formed otherwise, the layer forming step is separately performed to form a layer over the to-be-removed region.

Thereafter, the substrate is removed from the second-plane side of the base portion. Here, the to-be-removed region is preferably removed together. If, however, the to-be-removed region is not removed together, it will be removed separately.

The second alignment mark appears on the second-plane side of the base portion by removing the to-be-removed region. The second alignment mark is a trace of removing the to-be-removed portion which is formed from the first-plane side. It is in alignment with the device structure on the first-plane side. Therefore, using the second alignment mark as a positional reference makes it possible to form a device structure that is in alignment with the device structure on the first-plane side, on the second-plane side of the base portion. As a result, it becomes possible to fabricate a device with double-sided structure in precise alignment.

Moreover, in the above-described device fabrication method, the device structure on either side is formed in accordance with the respective positional references (the positional reference on the first-plane side, the alignment mark on the second-plane side). Accordingly, there is no need to use the alignment marks on the opposite sides as the positional references, so that the conventional double side aligners and infrared aligners are not particularly required. On that account, it is possible to fabricate a device where alignment of its double-sided structure is required, by employing common fabrication apparatus.

Another device fabrication method according to the present invention comprises the steps of: forming a base portion of a device on a first-plane side of a substrate; forming a to-be-opened region in a to-be-opened area of the base portion during or after the process of forming the base portion, the to-be-opened region reaching the substrate and being selectively removable; and removing the substrate and the to-be-opened region from a second-plane side of the base portion, or the opposite side of the first-plane side, so that an opening hole (a trace of the removed to-be-opened region) appears on the second-plane side of the base portion.

In the device fabrication method, the base portion of a device is formed on the first-plane side of the substrate. During or after the formation of the base portion, a to-be-opened region piercing through the substrate is formed in a to-be-opened area of the base portion.

Thereafter, the substrate is removed from the second-plane side of the base portion. Here, the to-be-opened region is preferably removed together. If, however, the to-be-opened region is not removed together, then it will be removed separately. An opening hole which is a trace of the to-be-opened region removed, appears on the second-plane side of the base portion.

Since the opening hole is embedded in advance from the first-plane side as a to-be-opened region, the alignment between the device structure on the first-plane side and the opening hole can be achieved with easiness.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is a view of an image sensor 11 according to a first embodiment, as seen from its second-plane side;

FIG. 2 is a sectional view of the image sensor 11;

FIG. 3 is a diagram explaining a first method of fabricating the image sensor 11;

FIG. 4 is a diagram explaining a first method of fabricating the image sensor 11;

FIG. 5 is a diagram explaining a second method of fabricating the image sensor 11;

FIG. 6 is a diagram explaining a second method of fabricating the image sensor 11;

FIG. 7 is a potential chart explaining a charge accumulating operation and a charge transporting operation;

FIG. 8 is a potential chart explaining a dark current suppressing operation on the first-plane side;

FIG. 9 is a potential chart explaining an excessive charge discharging operation;

FIG. 10 is a potential chart explaining a charge read operation;

FIG. 11 is a sectional view of an image sensor 51 according to a second embodiment;

FIG. 12 is a diagram explaining a charge transporting operation in the image sensor 51;

FIG. 13 is a view of an image sensor 511 according to a third embodiment, as seen from its second-plane side;

FIG. 14 is a sectional view of the image sensor 511;

FIG. 15 is a chart showing the net impurity concentration in the A-A′ part shown in FIG. 14;

FIG. 16 is a diagram showing a first method of fabricating the image sensor 511;

FIG. 17 is a diagram showing a first method of fabricating the image sensor 511;

FIG. 18 is a diagram explaining a second method of fabricating the image sensor 511;

FIG. 19 is a diagram explaining a second method of fabricating the image sensor 511;

FIG. 20 is a potential chart explaining a charge accumulating operation and a charge transporting operation;

FIG. 21 is a potential chart explaining a discharge operation upon overflow;

FIG. 22 is a potential chart explaining signal charge transfer and read operations;

FIG. 23 is a potential chart explaining signal charge transfer and read operations;

FIG. 24 is a diagram showing an image sensor 551 according to a fourth embodiment;

FIG. 25 is a diagram explaining a charge read operation in the image sensor 551 according to the fourth embodiment;

FIG. 26 is a diagram showing an image sensor 552 according to a fifth embodiment;

FIG. 27 is a diagram explaining transfer and read operations in the image sensor 552 according to the fifth embodiment;

FIG. 28 is a diagram showing an exposure apparatus 60 according to a sixth embodiment;

FIG. 29 is a diagram showing an exposure apparatus 70 according to a seventh embodiment;

FIG. 30 is a diagram showing the fabrication steps according to an eighth embodiment;

FIG. 31 is a diagram showing the fabrication steps according to the eighth embodiment;

FIG. 32 is a diagram showing the fabrication steps according to a ninth embodiment;

FIG. 33 is a diagram showing the fabrication steps according to a tenth embodiment;

FIG. 34 is a diagram showing another reinforcing structure of an image sensor;

FIG. 35 is a diagram explaining a third method of fabricating the image sensor 511; and

FIG. 36 is a diagram showing a conventional example of a back-illuminated image sensor.

### DETAILED DESCRIPTION OF THE PREFERRED EMBODIMENTS

Hereinafter, embodiments of the present invention will be described with reference to the drawings.

<First Embodiment>

The first embodiment corresponds to the invention set forth in claims 1-7, 10, and 51.

[Configuration of the Image Sensor 11]

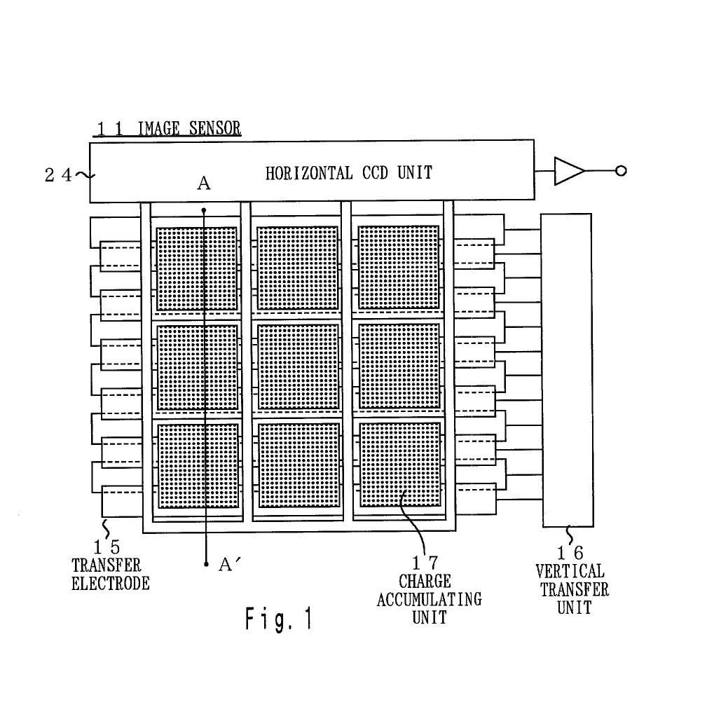

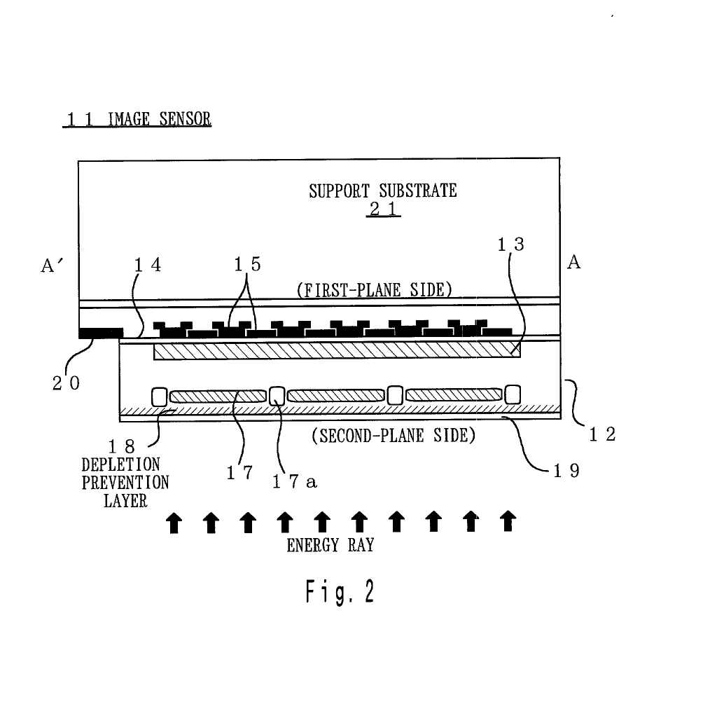

FIG. 1 is a schematic view of an image sensor 11 as seen from its second-plane side. FIG. 2 is an A-A′ cross section of the image sensor 11. Hereinafter, the configuration of the image sensor 11 will be described with reference to FIGS. 1 and 2.

Initially, the image sensor 11 is provided with a P-type semiconductor base 12. In each pixel row, an N-type CCD diffusion layer 13 is buried in the first-plane side of the semiconductor base 12. The CCD diffusion layer 13 has a plurality of transfer electrodes 15 arranged thereon across a gate oxide film 14. The voltages of the transfer electrodes 15 are controlled by a vertical transfer unit 16. In addition, a horizontal CCD unit 24 is arranged over the outputting ends of the CCD diffusion layers 13.

Meanwhile, N-type charge accumulating units 17 are buried in the second-plane side of the semiconductor base 12 on a pixel-by-pixel basis, facing the CCD diffusion layers 13. The charge accumulating units 17 are electrically isolated from each other via P⁺-type buried channel stops 17a.

A P-type depletion prevention layer 18 is arranged on the second-plane side of the charge accumulating units 17. The depletion prevention layer 18 is set at such a thickness that energy rays to be detected can sufficiently pass through, and at such an impurity concentration rate as prevents the surface depletion of the charge accumulating units 17.

Additionally, the image sensor 111 is provided with an antireflection film 19, bonding pads 20, a support substrate 21, and so on.

[Correspondences between the Present Invention and the First Embodiment]

Hereinafter, description will be given of the correspondences between the present invention and the first embodiment. Note that these correspondences are intended to provide an interpretation for reference purposes, not to limit the present invention in vain.

The following are the correspondences between the inventions set forth in claims 1-4 and the first embodiment. The semiconductor base corresponds to the semiconductor base 12. The charge transfer unit corresponds to the CCD diffusion layers 13, the gate oxide film 14, and the transfer electrodes 15. The charge accumulating units correspond to the charge accumulating units 17. The depletion prevention layer corresponds to the depletion prevention layer 18. The charge transport unit corresponds to “the configuration of transporting the signal charges in the charge accumulating units 17 to the CCD diffusion layers 13 under the voltage control of the transfer electrodes 15” in the vertical transfer unit 16.

As for the correspondences between the invention set forth in claim 5 and the first embodiment in addition to the correspondences mentioned above, the invalid charge discharging unit corresponds to “the configuration of discharging invalid charges through the CCD diffusion layers 13” in the vertical transfer unit 16.

As for the correspondences between the invention set forth in claim 6 and the first embodiment, aside from the correspondences mentioned above, the dark current suppressing unit corresponds to “the configuration of approximating the first-plane-side potentials of the CCD diffusion layers 13 to the substrate potential so as to suppress dark current inflows” in the vertical transfer unit 16.

As for the correspondences between the invention set forth in claim 7 and the first embodiment, aside from the correspondences mentioned above, the excessive charge discharging unit corresponds to “the configuration of discharging excessive charges overflowing out of the charge accumulating units 17 through the CCD diffusion layers 13” in the vertical transfer unit 16.

[First Fabrication Method]

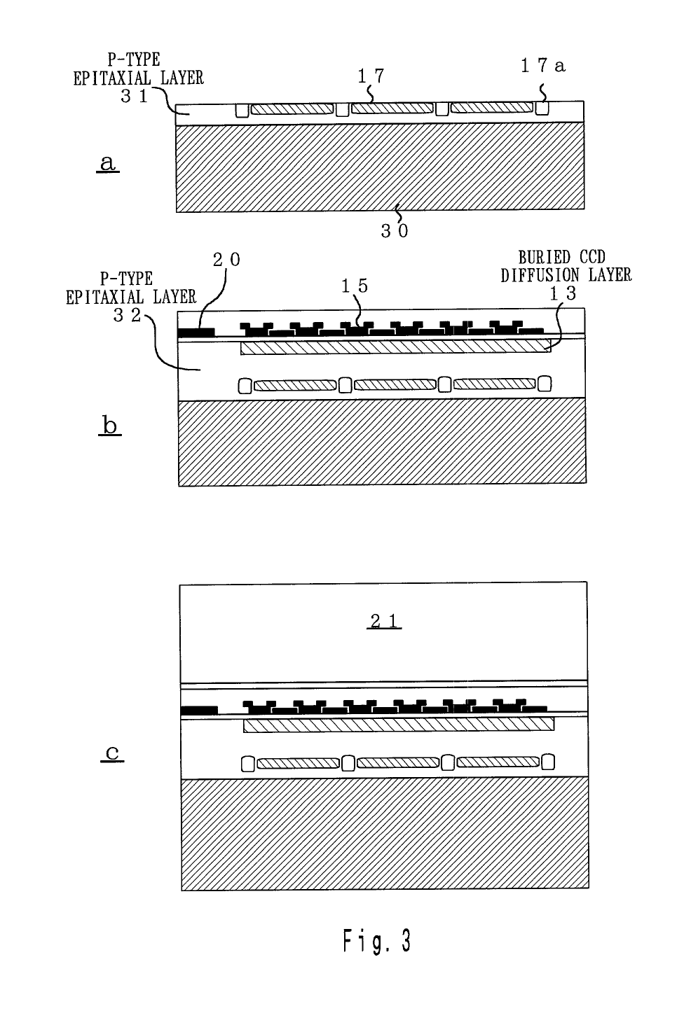

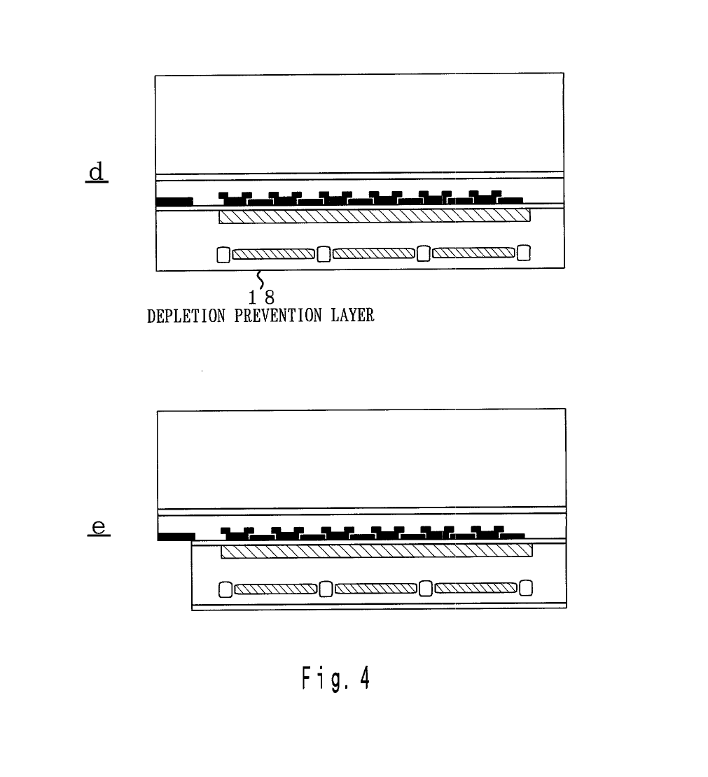

FIGS. 3 and 4 are diagrams explaining a first method of fabricating the image sensor 11. Hereinafter, the first method of fabricating the image sensor 11 will be described with reference to FIGS. 3 and 4. Incidentally, a photolithographic process and other publicly-known processes will be omitted from the description.

For a start, a P-type epitaxial layer 31 of approximately 1E15/cm³ in concentration and 4 μm in thickness is vapor-grown on a P⁺-type substrate 30 of approximately 1E18/cm³ in concentration. Here, steps (resulting from dry etching or a difference in oxidation rate) are formed in part of the surface of the P-type epitaxial layer 31 so that they are used as an alignment mark (not shown). The P-type epitaxial layer 31 is coated with a protective oxide film, followed by As ion implantation under the conditions of 180 keV in acceleration voltage and 7E11/cm² in dose to form regions to be the charge accumulating units 17. Moreover, B ions are implanted under the conditions of 60 keV in acceleration voltage and 1E13 /cm² in dose to form regions to be the channel stops 17a. Thereafter, annealing is performed so that the protective oxide film is removed to provide the state shown in FIG. 3a.

Next, a P-type epitaxial layer 32 of approximately 1E15/cm³ in concentration and 4 μm in thickness is vapor-grown on the surface of the P-type epitaxial layer 31. Here, the concentration and thickness of the P-type epitaxial layer 32 are determined so as to satisfy the condition that the CCD diffusion layers 13 and the charge accumulating units 17 be electrically isolated from each other upon the transfer operations of the CCD diffusion layers 13. Thus, given that the P-type epitaxial layer 32 has a thickness of e.g. 6 μm or so, the concentration is suitably conditioned around 5E14/cm³.

Next, the alignment mark on the P-type epitaxial layer 31 is put anew before CCD diffusion layers 13, a gate oxide film 14, transfer electrodes 15, and others are formed according to the same procedures as those for a frame transfer type CCD. Then, through planarization and the formation of AL wiring, a passivation film, and the like, the wafer shown in FIG. 3b is obtained.

Next, the wafer is subjected to SOG (Spin On Glass) processing or the like, whereby the portions above the epitaxial layers are planarized to a thickness of 10 μm or so. If necessary, planarization processing such as CMP (Chemical Mechanical Polishing) and mechanical polishing is performed here. Subsequently, a lightly doped silicon substrate to be the support substrate 21 is pasted on to provide the state shown in FIG. 3c.

Next, in a solution of hydrofluoric acid 1:nitric acid 3:acetic acid 8, etching is performed to remove the P⁺-type substrate 30. Here, the fact that P⁺ silicon is faster than P⁻ silicon in etching rate is utilized for etching control. Here, the layer region of approximately 1E17/cm³ with slower etching rate remains at the interface with the P-type epitaxial layer 31, which forms the depletion prevention layer 18. FIG. 4d shows the state described above.

Next, an antireflection film 19 is formed based on a sputtering method, thereby resulting in the state shown in FIG. 4e.

Subsequently, the silicon below the pad portions is opened by dry etching or the like, followed by such steps as dicing and packaging to complete the image sensor 11.

In this connection, through further experiments, the present inventors have found another set of suitable conditions. Hereinafter, description will be given of the alternative set of conditions.

Initially, a P-type epitaxial layer 31 of approximately 3E15/cm³ in concentration and 4 μm in thickness is vapor-grown on a P⁺-type substrate 30 of approximately 1E18/cm³ in concentration. Incidentally, steps (resulting from dry etching or a difference in oxidation rate) are formed in part of the surface of the P-type epitaxial layer 31 so as to be used as an alignment mark (not shown). The P-type epitaxial layer 31 is coated with a protective oxide film, followed by As ion implantation under the conditions of 180 keV in acceleration voltage and 6E12/cm² in dose to form the regions to be the charge accumulating units 17. Moreover, B ions are implanted under the conditions of 60 keV in acceleration voltage and 1E13/cm² in dose to form the regions to be the channel stops 17a. Thereafter, annealing is performed so that the protective oxide film is removed to provide the state shown in FIG. 3a.

Next, a P-type epitaxial layer 32 of approximately 3E15/cm³ in concentration and 3 μm in thickness is vapor-grown on the surface of the P-type epitaxial layer 31. Here, the concentration and thickness of the P-type epitaxial layer 32 are determined so as to satisfy the condition that the CCD diffusion layers 13 and the charge accumulating units 17 be electrically isolated from each other upon the transfer operations of the CCD diffusion layers 13. Thus, given that the P-type epitaxial layer 32 has a thickness of e.g. 6 μm or so, the concentration is suitably conditioned around 5E14/cm^{3.}

The subsequent processes (such as the formation of the CCD diffusion layers 13) are performed in the same manner as described above.

[Second Fabrication Method]

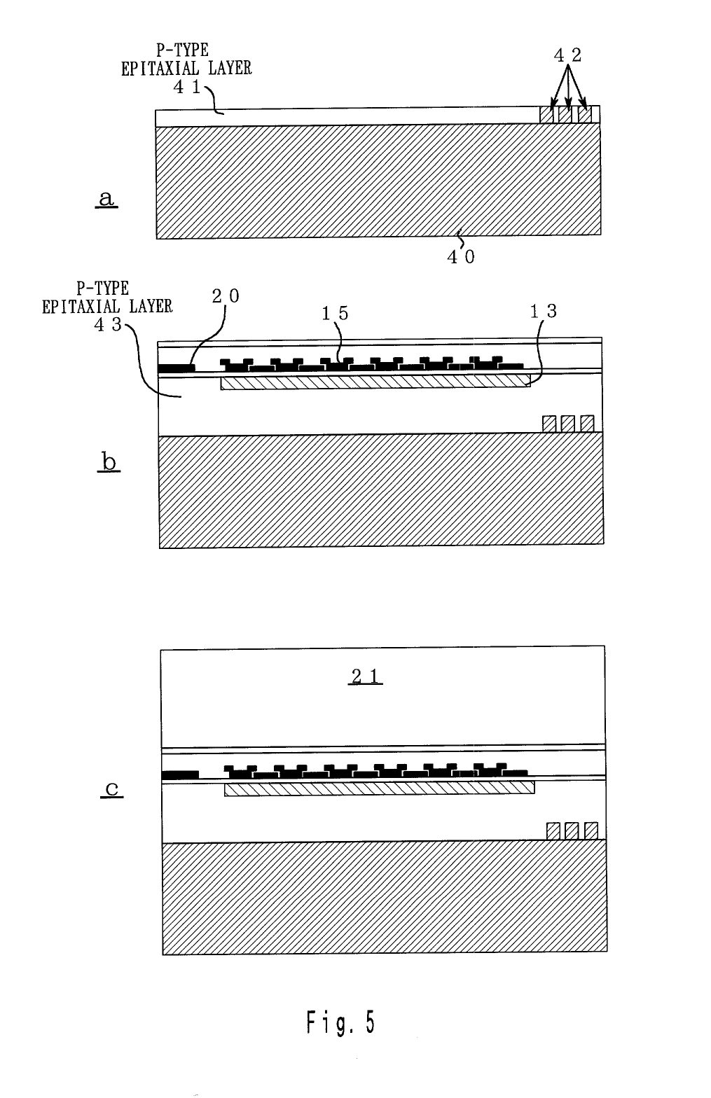

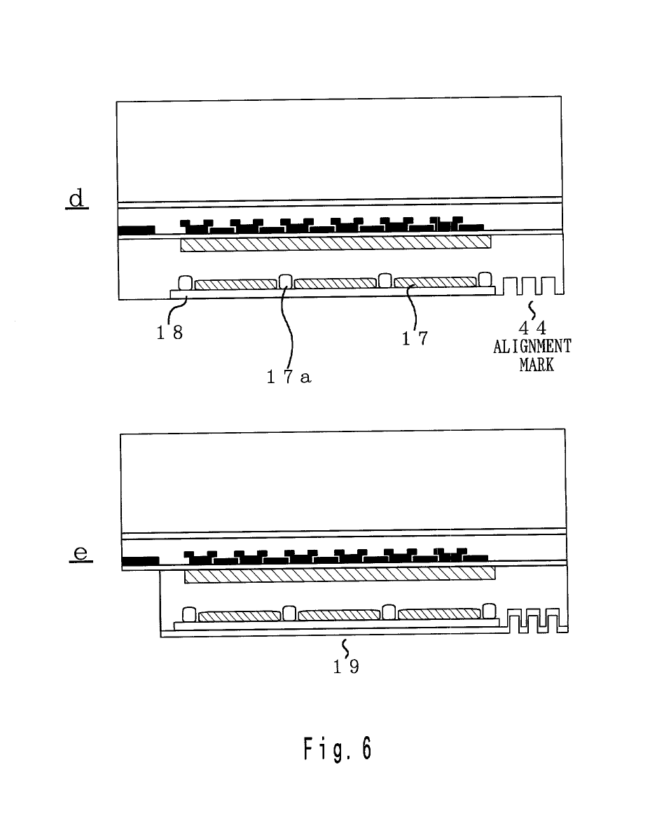

FIGS. 5 and 6 are diagrams explaining a second method of fabricating the image sensor 11. Hereinafter, the second fabrication method will be described with reference to FIGS. 5 and 6.

For a start, a P-type epitaxial layer 41 of approximately 5E14/cm³ in concentration and 4 μm in thickness is vapor-grown on a P⁺-type substrate 40 of approximately 1E18/cm³ in concentration (corresponding to the base forming step in claim 51).

Here, P⁺-type impurity regions 42 are formed in part of the p-type epitaxial layer 41 based on ion implantation or thermal diffusion (corresponding to the to-be-removed region forming step in claim 51). FIG. 5a shows the state described above.

Note that the impurity regions 42 may be any heavily doped impurity regions including N⁺-type impurity regions. For example, Sb (antimony) is preferably used as the N-type impurities in the impurity regions 42. Moreover, Sb preferably has a concentration rate greater than or equal to 1E18/cm³. The reason why Sb is preferred here is that it can suppress auto doping (a phenomenon in which impurities in a substrate are emitted into the atmosphere due to high temperature, and are re-doped into growing layers) in the subsequent step (the vapor phase growth of a P-type epitaxial layer 43). The auto doping has an enormous effect on the shapes of the impurity regions 42. As a result, an alignment mark 44 to be described later might be distorted so greatly that it fails to function as a mark. The above-mentioned Sb, however, has a property against the auto doping. Thus, selecting Sb as impurities in the impurity regions 42 allows the alignment mark 44 to be formed in a favorable shape.

Next, a P-type epitaxial layer 43 of approximately 5E14/cm³ in concentration and 4 μm in thickness is vapor-grown on the P-type epitaxial layer 41 (corresponding to the base forming step and the layer forming step in claim 51).

CCD diffusion layers 13, a gate oxide film 14, transfer electrodes 15, and others are formed on the P-type epitaxial layer 43, in the same procedures as those for a frame transfer type CCD. Then, planarization and the formation of AL wiring, a passivation film, and the like are performed to obtain the wafer shown in FIG. 5b.

Next, the wafer is subjected to such planarization processing as SOG (Spin On Glass), so that the portions above the epitaxial layers are adjusted to a thickness of 10 μm or so. If necessary, planarization processing such as CMP (Chemical Mechanical Polishing) and mechanical polishing is performed here. Subsequently, a lightly doped silicon substrate to be the support substrate 21 is pasted on to provide the state shown in FIG. 5c.

Next, in a solution of hydrofluoric acid 1:nitric acid 3:acetic acid 8, etching is performed to remove the P⁺-type substrate 40 (corresponding to the thinning step described in claim 10).

Here, the heavily doped P⁺-type impurity regions 42 are also removed to form an alignment mark 44 (corresponding to the removing step described in claim 51). The alignment mark 44 is used at the step of working the second-plane side to be described later (corresponding to the processing step described in claim 51); that is, it is used to achieve alignment in forming the charge accumulating units 17, the channel stops 17a, the depletion prevention layer 18, and the like.

More specifically, the P-type epitaxial layer 41 is coated with a protective oxide film at its second-plane side, followed by As ion implantation under the conditions of 180 keV in acceleration voltage and 3E12/cm² in dose to form the regions to be the charge accumulating units 17 (corresponding to the accumulating unit forming step described in claim 10).

Moreover, B ions are implanted under the conditions of 150 keV in acceleration voltage and 1E13/cm² in dose to form the regions to be the channel stops 17a.

Boron fluoride is ion-implanted under the conditions of 120 keV in acceleration voltage and 3E13/cm² in dose. This forms the region to be the depletion prevention layer 18 (corresponding to the layer forming step described in claim 10).

The impurity regions formed thus are locally annealed with laser or the like so as not to expose the AL wiring and the like to high temperatures. FIG. 6d shows the state described above.

Next, an antireflection film 19 is formed based on a sputtering method, and a pad opening is made from the second-plane side to provide the state of FIG. 6e.

This is followed by such steps as dicing and packaging to complete the image sensor 11.

[Description of the Operation of the Image Sensor 11]

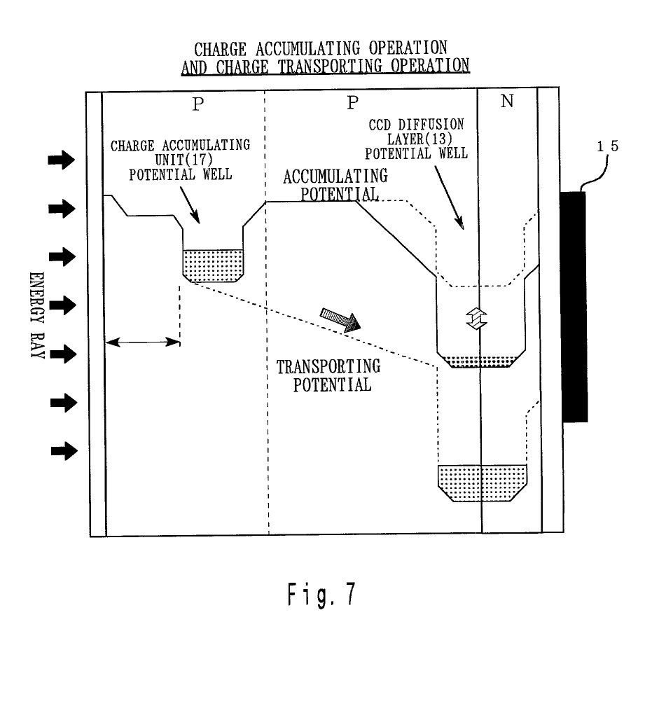

FIGS. 7 through 10 are potential charts for explaining the operation of the image sensor 11. Hereinafter, the operation of the image sensor 11 will be described with reference to the potential charts.

Initially, as shown in FIG. 7, most of the energy rays pass through the depletion prevention layer 18 to reach the depletion regions in the charge accumulating units 17, generating electron-hole pairs. The electrons generated here are attracted and accumulated into the potential wells in the charge accumulating units 17, thereby making signal charges.

On the other hand, the interface between the antireflection film 19 and the silicon, if depleted, would generate large number of dark currents. In the present invention, however, the depletion prevention layer lies on the interface. This makes it possible to inhibit (prevent) dark current from going into the charge accumulating units.

The conceivable reasons for such an inhibiting effect include: \mathring{1} the surface potential fixed to the substrate potential, dark current are hard to occur, and \mathring{2} dark current recombine and disappear while diffusing and moving through the depletion prevention layer 18.

When a charge accumulating time is extended in order to detect weak light, the dark current accumulated into the CCD diffusion layers 13 become not negligible. For this reason, the vertical transfer unit 16, during the charge accumulating period, successively applies a transfer voltage to the transfer electrodes 15 to discharge invalid charges out of the CCD diffusion layers 13, so that the dark current are suppressed as much as possible.

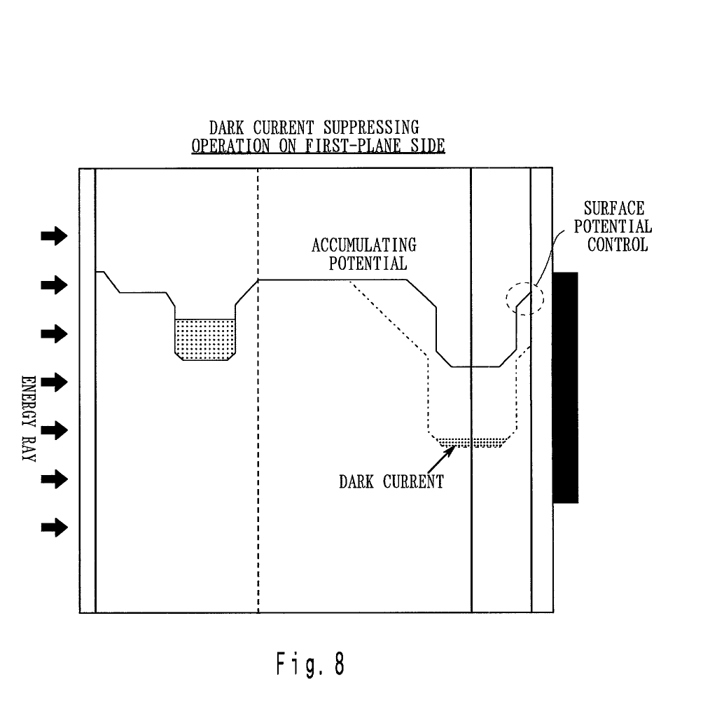

Moreover, at pixels from which the invalid charges are discharged, the vertical transfer unit 16 fixes the transfer electrodes 15 to a negative voltage in succession and approximates the surface potentials of the CCD diffusion layers 13 to the substrate potential. Due to the operations, holes gather near the surfaces of the CCD diffusion layers 13 to prevent the CCD diffusion layers 13 from surface depletion. Consequently, as shown in FIG. 8, dark current that go into the CCD diffusion layers 13 can be greatly suppressed during the period of negative voltage application.

Due to both of or either of the effects, dark current can be suppressed to a negligible level even in the cases of accumulating weak light for a long time.

On the other hand, when illuminated with strong light, the potential wells in the charge accumulating units 17 are saturated to let excessive charges flow out. The conventional back-illuminated image sensor was provided with lateral overflow drains in order to prevent excessive charges from overflowing the potential wells of the CCD diffusion layers to cause a phenomenon of blurring the sensed image (so-called blooming). For that reason, the image sensor conventionally had to degrade its opening ratio corresponding to the sizes of the lateral overflow drains.

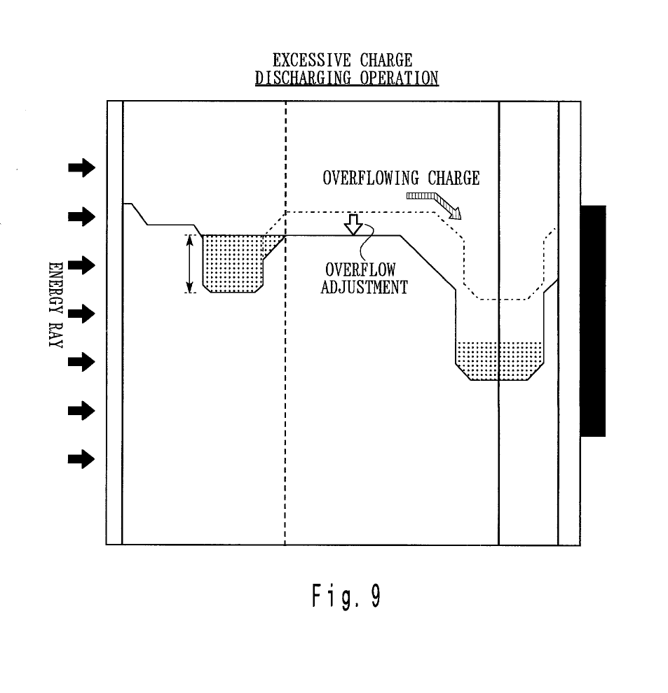

Nevertheless, the image sensor 11 of the present invention, as shown in FIG. 9, adjusts the voltages applied to the transfer electrodes 15, so that excessive charges out of the charge accumulating units 17 overflow into the CCD diffusion layers 13. The excessive charges are discharged to exterior along with the dark current described above. Therefore, the blooming phenomenon can be improved without degrading the opening ratio of the image sensor.

When the charge accumulating time is thus ended, the vertical transfer unit 16 applies a voltage of the order of 15 V to the transfer electrodes 15. Due to the voltage application, the signal charges in the charge accumulating units 17 are attracted and transported to the respective potential wells in the CCD diffusion layers 13 on a pixel-to-pixel basis.

Here, the charge accumulating units 17 come to full depletion.

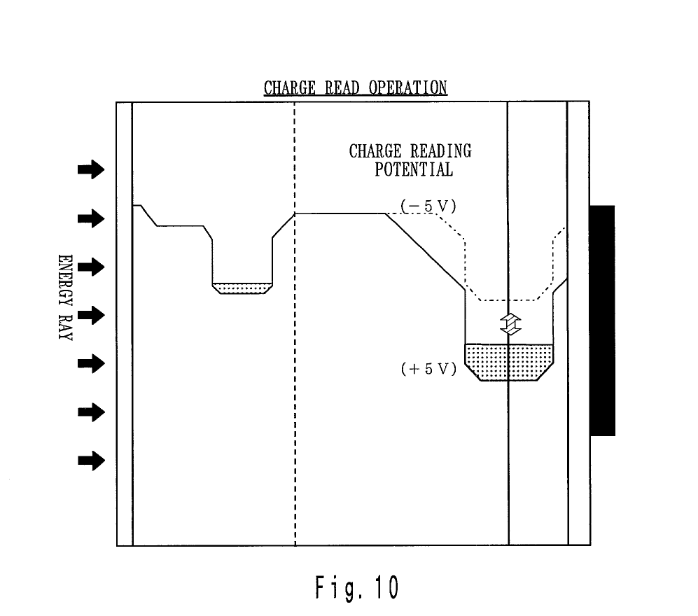

Subsequently, the vertical transfer unit 16, as shown in FIG. 10, successively applies transfer voltages of approximately ±5 V to the transfer electrodes 15 so that the signal charges in the CCD diffusion layers 13 are read out in succession.

[Effects of the First Embodiment]

In the first embodiment described above, the charge accumulating units 17 are arranged on the second-plane side, opposite to the CCD diffusion layers 13. This allows a substantial reduction in the traveling distances of the signal charges on the second-plane side. As a result, it becomes possible to improve the efficiency of energy ray detection and the production of smear. In particular, the above-mentioned improvements become more significant when the traveling distances are longer (when signal charges are generated at very shallow depth in the second plane as under ultraviolet rays).

Besides, in the first embodiment, the dark current are suppressed greatly owing to a synergistic effect of the depletion prevention layer 18, the discharging of the dark current, the prevented surface depletion of the CCD diffusion layers 13, and so on. Accordingly, it becomes possible to obtain relatively favorable imaging quality even under severe conditions such as weak light detection.

Furthermore, in the first embodiment, the provision of the depletion prevention layer 18 makes it possible to eliminate the backside wells on the second-plane side. This reduces the possibility that signal charges be captured in the backside wells, and thus allows a further improvement in the efficiency of energy ray detection.

Moreover, in the first embodiment, the excessive charges overflowing the charge accumulating units 17 are discharged through the CCD diffusion layers 13. Therefore, the blooming phenomenon resulting from excessive charges can be suppressed with reliability.

Besides, in the first embodiment, the charge accumulating units 17 arranged on the second-plane side intercept the free flow of signal charges, so that few charges might go into the CCD diffusion layers 13 during charge transfer. This eliminates the need to shield the second-plane side during the charge transfer, thereby permitting the omission of mechanical shutters. In particular, high shielding effects can be obtained in the cases where the signal charges are generated at very shallow depth in the second plane as under ultraviolet rays.

Moreover, in the second fabrication method described above, the charge accumulating units 17 and the depletion prevention layer 18 are formed from the second-plane side. This allows precise control over the surface depth of the depletion prevention layer 18 and the like.

Furthermore, in the above-described second fabrication method, the P⁺-type impurity regions 42 are embedded at the time of processing the first-plane side of the image sensor 11. Thereafter, the P⁺-type impurity regions 42 are removed from the second-plane side to form the alignment mark 44 on the second-plane side of the image sensor 11. By using the alignment mark 44 as a positional reference, a device structure in alignment with the processing to the first-plane side can be formed on the second-plane side of the image sensor 11.

Now, description will be given of another embodiment.

<Second Embodiment>

The second embodiment corresponds to the inventions set forth in claims 1-10.

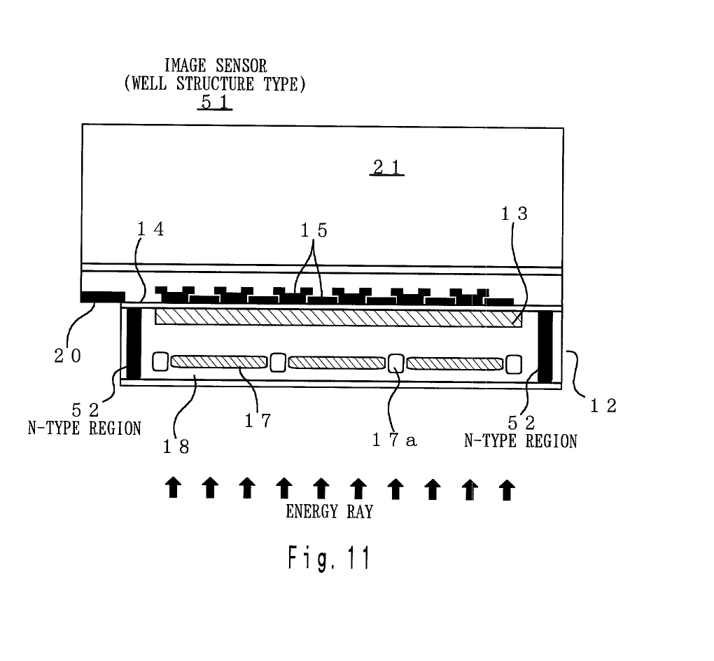

FIG. 11 is a sectional view of an image sensor 51 according to the second embodiment. Note that configurations common to those of the first embodiment (FIG. 2) are shown in FIG. 11 with identical numerals attached thereto. Description thereof will be omitted here.

A constitutional feature of the image sensor 51 lies in that the semiconductor base 12 is surrounded by an N-type region 52 (corresponding to the semiconductor region described in claim 9) so that the semiconductor base 12 has a well structure. Incidentally, the well structure may be fabricated by forming an N⁺-type impurity region in the semiconductor base 12 as an isolation. Otherwise, it may be fabricated by forming a well-shaped P-type semiconductor 12 in part of an N-type semiconductor.

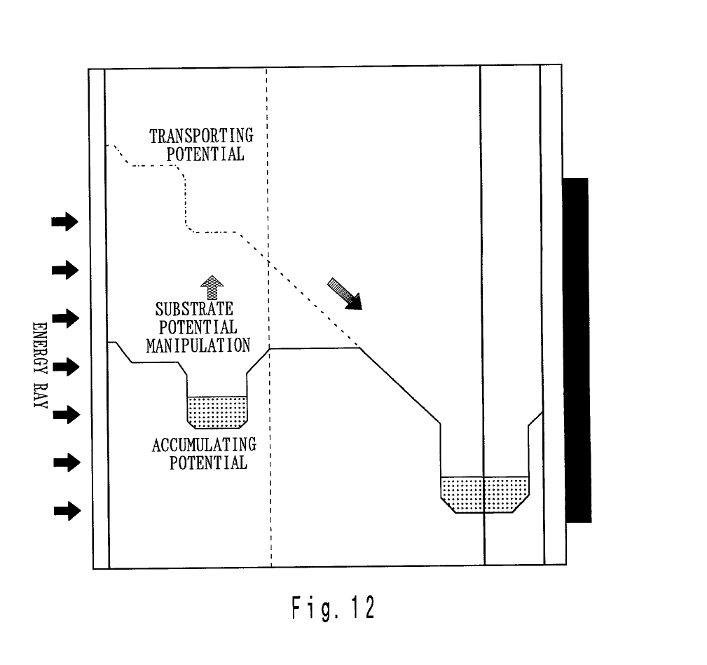

FIG. 12 is a potential chart for explaining the operation of the second embodiment.

In the second embodiment, as shown in FIG. 12, a negative voltage of the order of −15 V is applied to the substrate-potentialed terminal of the semiconductor base 12 to provide charge transportation from the charge accumulating units 17 to the CCD diffusion layers 13 (corresponding to the charge transport unit described in claim 8).

In such charge transportation, the direct control of the potentials of the charge accumulating units 17 ensures the charge transportation. Therefore, the charge accumulating units 17 can be made greater in the amount of saturation charge.

Besides, the semiconductor base 12 having a well structure is small in size, and thus is low in capacitance. Therefore, it becomes possible to drive the substrate potential of the semiconductor base 12 with smaller current at higher speed, so that the charge transporting operation can be performed at even higher speed.

Now, description will be given of another embodiment.

<Third Embodiment>

The third embodiment is of the image sensors corresponding to the inventions set forth in claims 1-4 and 11-18.

[Configuration of the Image Sensor]

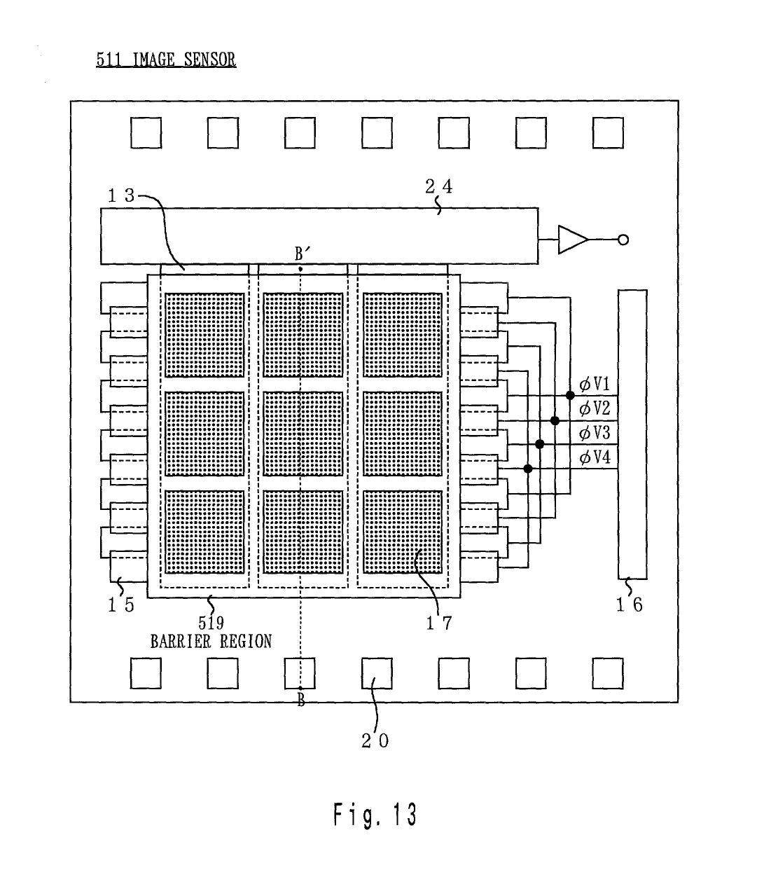

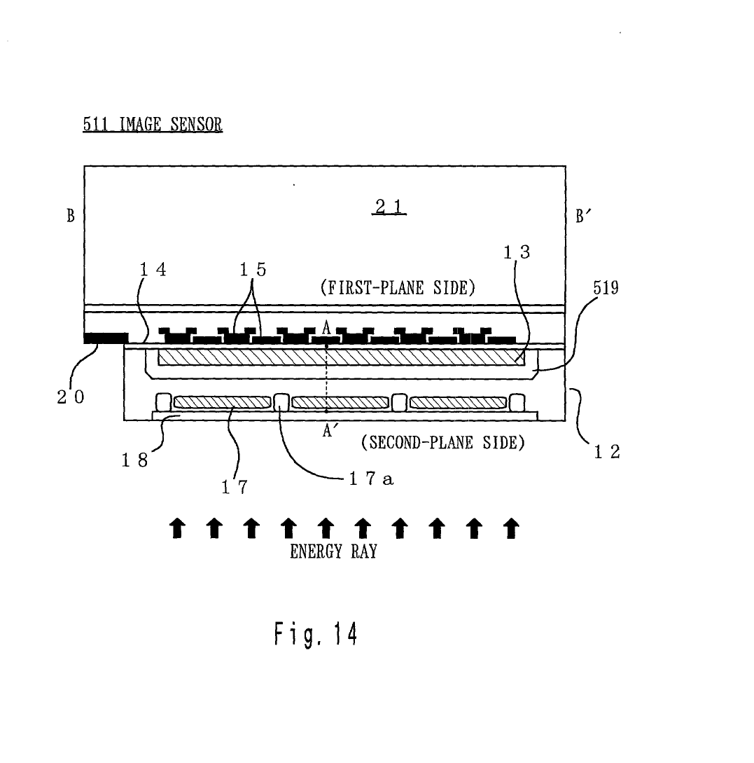

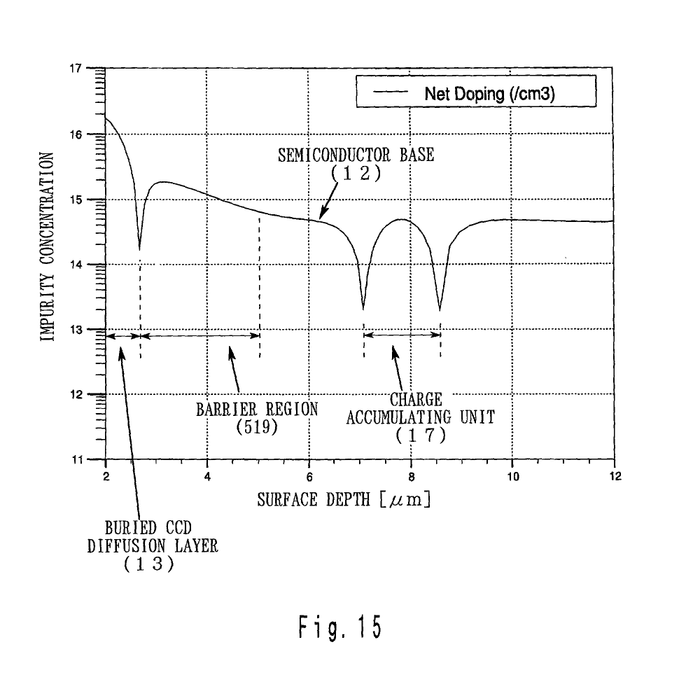

FIG. 13 is a diagram showing an image sensor 511 according to the third embodiment. FIG. 14 is a diagram showing the sectional structure along the B-B′ part shown in FIG. 13. FIG. 15 is a chart showing the net impurity concentration in the A-A′ part shown in FIG. 14.

A constitutional feature of the third embodiment lies in that as shown in FIGS. 13 and 14, a barrier region 519 is arranged between the charge accumulating units 17 and the CCD diffusion layers 13 so as to intercept the charge transporting paths. The barrier region 519 has an impurity concentration distribution of P-type as shown in FIG. 15. The semiconductor base 12 is previously set to be lower than the barrier region 519 in P-type impurity concentration rate.

Note that components common to those of the first embodiment (FIGS. 1 and 2) are shown in FIGS. 13-15 with identical numerals attached thereto. Here, repetitive Description thereof will be omitted.

[Correspondences between the Present Invention and the Third Embodiment]

Hereinafter, description will be given of the correspondences between the present invention and the third embodiment. Incidentally, the correspondences are intended to provide an interpretation for reference purposes, not to limit the present invention in vain.

The following are the correspondences between the inventions set forth in claims 1-4 and the third embodiment. The semiconductor base corresponds to the semiconductor base 12. The charge transfer unit corresponds to the CCD diffusion layers 13, the gate oxide film 14, and the transfer electrodes 15. The charge accumulating units correspond to the charge accumulating units 17. The depletion prevention layer corresponds to the depletion prevention layer 18. The charge transport unit corresponds to “the configuration of transporting the signal charges in the charge accumulating units 17 to the CCD diffusion layers 13 under the voltage control of the transfer electrodes 15” in the vertical transfer unit 16.

The following are the correspondences between the inventions set forth in claims 11-15 and the third embodiment. The semiconductor base corresponds to the semiconductor base 12. The charge transfer unit corresponds to the CCD diffusion layers 13, the gate oxide film 14, the transfer electrodes 15, and the vertical transfer unit 16. The charge accumulating units correspond to the charge accumulating units 17. The charge transport unit corresponds to “the configuration of transporting the signal charges in the charge accumulating units 17 to the CCD diffusion layers 13 under the voltage control of the transfer electrodes 15” in the vertical transfer unit 16. The barrier region corresponds to the barrier region 519.

[First Fabrication Method]

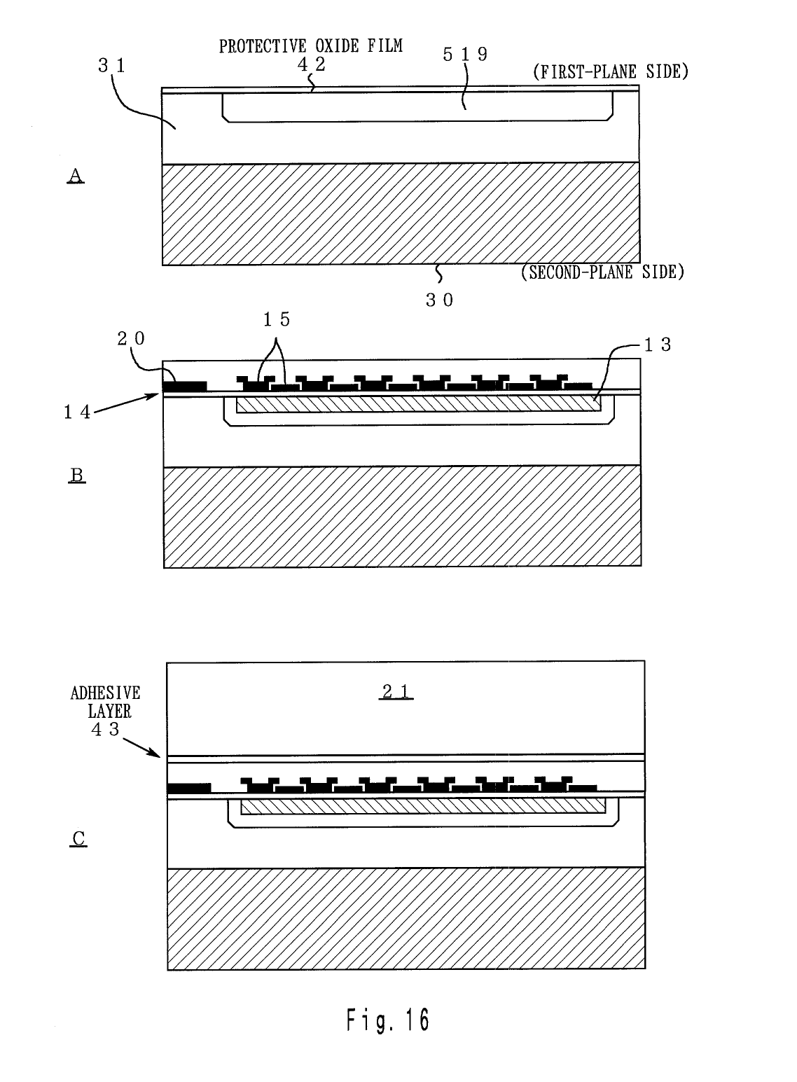

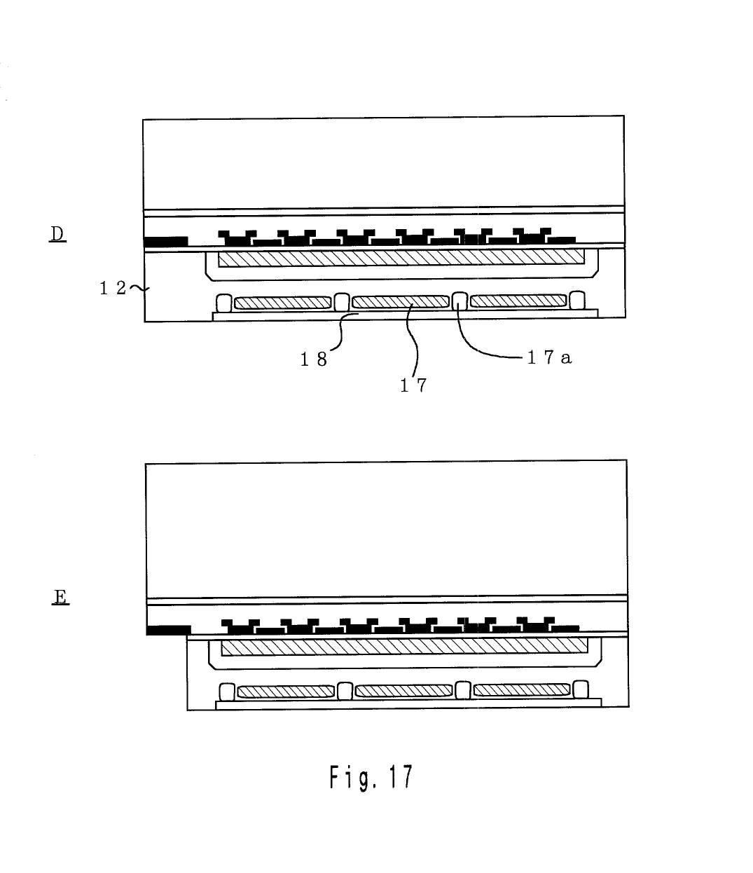

FIGS. 16 and 17 are diagrams explaining a first method of fabricating the image sensor 511. Hereinafter, the first method of fabricating the image sensor 511 will be described with reference to FIGS. 16 and 17. Incidentally, a photolithographic process and other publicly known processes will be omitted from the description.

For a start, a P⁻-type epitaxial layer 31 of approximately 5E14/cm³ in concentration and 12 μm in thickness is vapor-grown on a P⁺-type substrate 30 of approximately 1E18/cm³ in concentration (corresponding to the step of forming an epitaxial layer, described in claim 16). The P⁻-type epitaxial layer 31 is a region to be the semiconductor base 12.

A protective oxide film of the order of 500 Å is formed on the P⁻-type epitaxial layer 31, followed by B⁺ ion implantation under the conditions of 340 keV in acceleration voltage and 4E11/cm² in dose. The wafer in this state is subjected to driving-in in a nitrogen atmosphere under the conditions of 1150° C. and 360 minutes, to obtain a barrier region 519 (corresponding to the step of forming a barrier region, described in claim 16). This provides the waver shown in FIG. 16A.

Next, buried CCD diffusion layers 13, a gate oxide film 14, transfer electrodes 15, and N⁺ and P⁺ diffusion layers are formed in the same procedures as those for an ordinary frame transfer type CCD (corresponding to the step of forming a charge transfer unit, described in claim 16). Then, after a planarization step, AL wiring, bonding pads, a passivation film, and the like are formed. The steps described above provide the wafer shown in FIG. 16B.

Moreover, the first-plane side of the wafer is planarized based on SOG (Spin On Glass) processing, and a support substrate 21 is pasted thereon via an adhesive layer 43. Thereby is obtained the waver shown in FIG. 16C.

Next, in a solution of hydrofluoric acid 1:nitric acid 3:acetic acid 8, etching is performed to remove the P⁺-type substrate 30 (corresponding to the thinning step described in claim 16). Here, the fact that P⁺ silicon is faster than P⁻ silicon in etching rate is utilized for etching control. Before the etching, part of the P⁺ substrate may be removed by mechanical polishing or the like. Thereby is obtained the semiconductor base 12 having a thickness of 10 μm or so.

A protective oxide film is formed on the second-plane side of the semiconductor base 12, followed by As ion implantation under the conditions of 340 keV in acceleration voltage and 1E12/cm² in dose to form P⁺⁺-type charge accumulating units 17 (corresponding to the step of forming charge accumulating units, described in claim 16).

Then, B ions are implanted under the conditions of 50 keV in acceleration voltage and 3E12/cm² in dose to form channel stops 17a.

Furthermore, boron fluoride is ion-implanted under the conditions of 10 keV in acceleration voltage and 1E15/cm² in dose to form a depletion prevention layer 18.

The impurity regions formed thus are locally annealed with laser or the like so as not to expose the AL wiring and the like to high temperatures. FIG. 17D shows the state described above.

Next, an antireflection film and the like are formed based on a sputtering method. Then, etch-removing is applied to the positions of the bonding pads 20 and the like from the second-plane side, thereby obtaining the state shown in FIG. 17E. Finally, the image sensor 511 is completed through such steps as dicing and packaging.

[Second Fabrication Method]

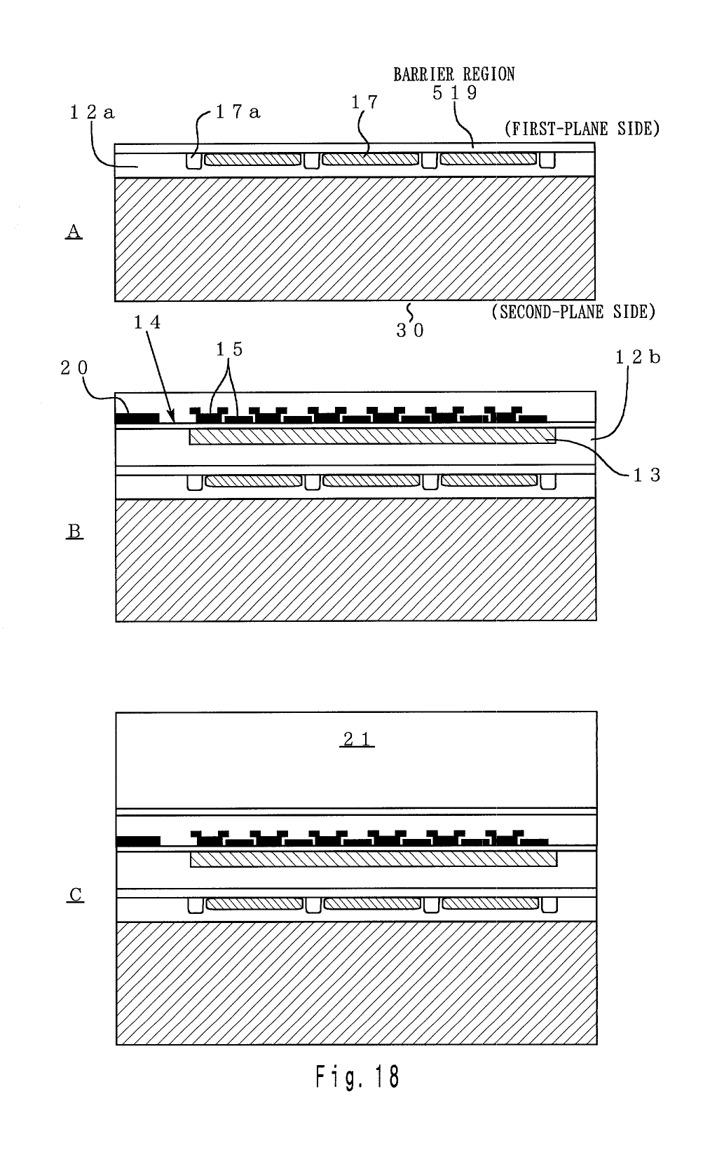

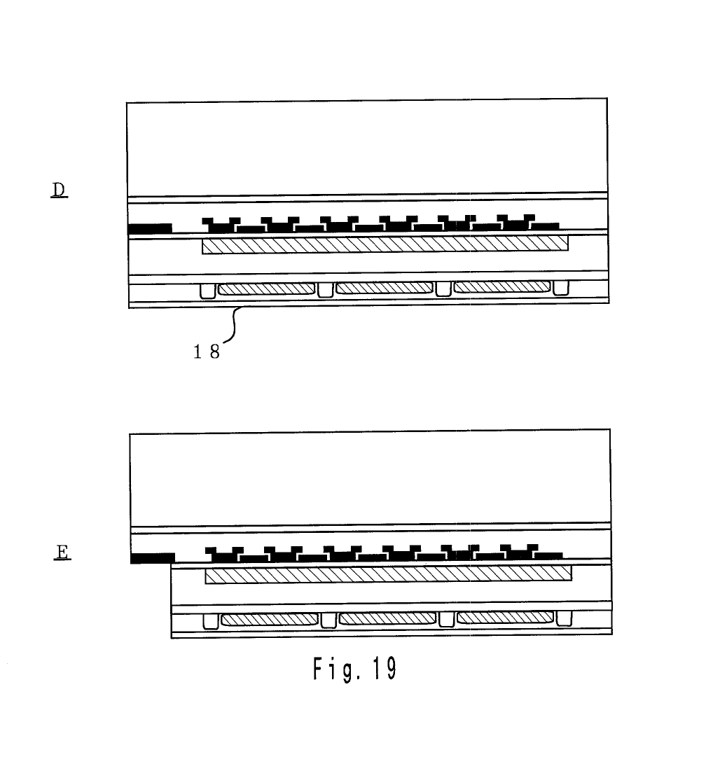

FIGS. 18 and 19 are diagrams explaining a second fabrication method according to the present invention. Hereinafter, the second fabrication method will be described with reference to FIGS. 18 and 19. Incidentally, a photolithographic process and other publicly known processes will be omitted from the description.

Initially, a P⁻-type first epitaxial layer 12a of approximately 5E14/cm³ in concentration and 6 μm in thickness is vapor-grown on a P⁺-type substrate 30 of approximately 1E18/cm³ in concentration (corresponding to the step of forming a first epitaxial layer, described in claim 17).

A protective oxide film is formed on the first epitaxial layer 12a, followed by As ion implantation under the conditions of 340 keV in acceleration voltage and 4E12/cm² in dose to form charge accumulating units 17 (corresponding to the step of forming charge accumulating units, described in claim 17).

Moreover, B ions are implanted under the conditions of 60 keV in acceleration voltage and 1E12/cm² in dose to form the regions to be the channel stops 17a.

Next, B ions are implanted under the conditions of 30 keV in acceleration voltage and 6E11/cm² in dose. This forms the region to be the barrier region 519 (corresponding to the step of forming a barrier region, described in claim 17).

Thereafter, annealing (1000° C., 30 min.) is performed in a nitrogen atmosphere so that the protective oxide film is removed to provide the state shown in FIG. 18A.

Next, a P⁻-type second epitaxial layer 12b of approximately 5E14/cm³ in concentration and 6 μm in thickness is vapor-grown on the surface of the first epitaxial layer 12a (corresponding to the step of forming a second epitaxial layer, described in claim 17).

Next, CCD diffusion layers 13, a gate oxide film 14, transfer electrodes 15, and others are formed in the same procedures as those for a frame transfer type CCD (corresponding to the step of forming a charge transfer unit, described in claim 17).

Thereafter, the wafer shown in FIG. 18B is obtained through planarization and the formation of AL wiring, a passivation film, and so on.

Then, the wafer is subjected to SOG (Spin On Glass) processing and the like. If necessary, planarization processing such as CMP (Chemical Mechanical Polishing) and mechanical polishing is performed here. Subsequently, a lightly doped silicon substrate to be the support substrate 21 is pasted on to provide the state shown in FIG. 18C.

Next, in a solution of hydrofluoric acid 1:nitric acid 3:acetic acid 8, etching is performed to remove the P⁺-type substrate 30 (corresponding to the thinning step described in claim 17).

Here, the fact that P⁺ silicon is faster than P⁻ silicon in etching rate is utilized for etching control. Here, the layer region of approximately 1E17/cm³ with slower etching rate remains at the interface with the first epitaxial layer 12a, which is to be the depletion prevention layer 18. FIG. 19D shows the state described above. Incidentally, the depletion prevention layer 18 may be formed by ion implantation and laser annealing.

Subsequently, the silicon below the pad portions is opened by dry etching or the like, followed by such processes as dicing and packaging to complete the image sensor shown in FIG. 19E.

[Third Fabrication Method]

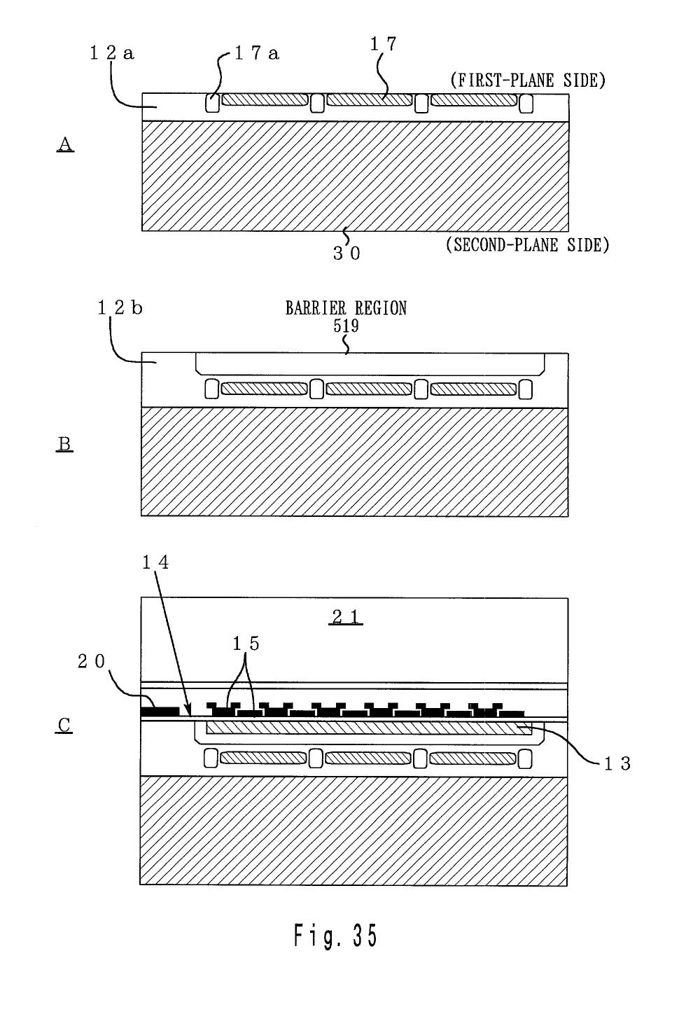

FIG. 35 is a diagram explaining a third fabrication method in the present invention. Hereinafter, the third fabrication method will be described with reference to FIG. 35. Incidentally, a photolithographic process and other publicly known processes will be omitted from the description.

Initially, a P⁻-type first epitaxial layer 12a of approximately 5E14/cm³ in concentration and 5 μm in thickness is vapor-grown on a P⁺-type substrate 30 of approximately 1E18/cm³ in concentration (corresponding to the step of forming a first epitaxial layer, described in claim 18).

A protective oxide film having a thickness of the order of 500 Å is formed on the first epitaxial layer 12a. The first epitaxial layer 12a is subjected to As ion implantation under the conditions of 340 keV in acceleration voltage and 4E12/cm² in dose, to form charge accumulating units 17 (corresponding to the step of forming charge accumulating units, described in claim 18).

Moreover, B ions are implanted under the conditions of 60 keV in acceleration voltage and 1E13/cm² in dose to form the regions to be the channel stops 17a.

Subsequently, annealing is performed in a nitrogen atmosphere to recover crystal defects. The steps described above provide the state shown in FIG. 35A.

Next, a P⁻-type second epitaxial layer 12b of approximately 5E14/cm³ in concentration and 5 μm in thickness is vapor-grown on the surface of the first epitaxial layer 12a (corresponding to the step of forming a second epitaxial layer, described in claim 18).

A protective oxide film having a thickness of the order of 500 Å is formed on the first-plane side of the second epitaxial layer 12b. Then, B ions are implanted under the conditions of 340 keV in acceleration voltage and 6E11/cm² in dose to form the region to be the barrier region 519 (corresponding to the step of forming a barrier region, described in claim 18).

Subsequently, annealing (1150° C., 360 min.) is performed in a nitrogen atmosphere. The steps described above provide the state shown in FIG. 35B.

Next, CCD diffusion layers 13, a gate oxide film 14, transfer electrodes 15, and others are formed in the same procedures as those for a frame transfer type CCD (corresponding to the step of forming a charge transfer unit, described in claim 18).

This is followed by planarization and the formation of AL wiring, a passivation film, and so on.

Then, the wafer is subjected to SOG (Spin On Glass) processing and the like. If necessary, planarization processing such as CMP (Chemical Mechanical Polishing) and mechanical polishing is performed here. Subsequently, a lightly doped silicon substrate to be the support substrate 21 is pasted on to provide the state shown in FIG. 35C.

Next, in a solution of hydrofluoric acid 1:nitric acid 3:acetic acid 8, etching is performed to remove the P⁺-type substrate 30 (corresponding to the thinning step described in claim 18). Here, the fact that P⁺ silicon is faster than P⁻ silicon in etching rate is utilized for etching control.

Then, a protective oxide film is formed on the second-plane side of the first epitaxial layer 12a before BF ions are implanted under the conditions of 100 keV in acceleration voltage and 1E15/cm² in dose. Moreover, the BF-ion-implanted layer is annealed with laser or the like so as not to expose the AL wiring and the like to high temperatures. This completes the depletion prevention layer 18.

Subsequently, the silicon below the pad portions is opened by dry etching or the like, followed by such processes as dicing and packaging to complete the image sensor 511 shown in FIG. 14.

[Description of the Operation of the Image Sensor 511]

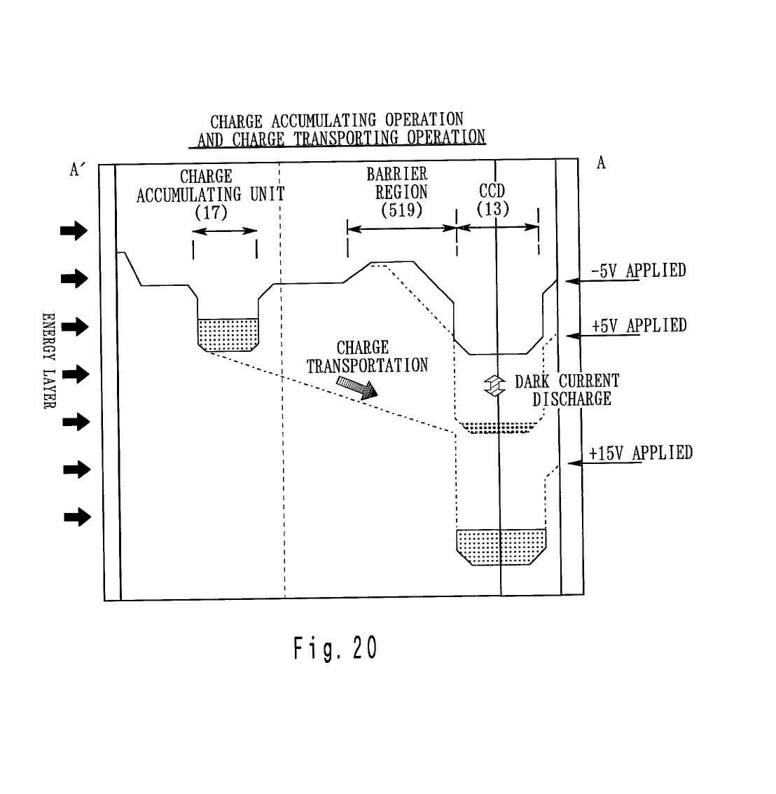

FIGS. 20 through 22 are potential charts for explaining the operation of the image sensor 511. Hereinafter, the operation of the image sensor 511 will be described with reference to the potential charts.

Initially, as shown in FIG. 20, most of the energy rays reach the charge accumulating units 17 to generate electron-hole pairs. The electrons generated here are attracted and accumulated into the potential wells in the charge accumulating units 17, thereby making signal charges.

In this state, the charge accumulating units 17 and the CCD diffusion layers 13 are electrically isolated from each other by the peak of the potential barrier created by the barrier region 519.

When a charge accumulating time is extended in order to detect weak light, the dark current accumulated into the CCD diffusion layers 13 become not negligible. On that account, the vertical transfer unit 16, during the charge accumulating period, successively applies transfer voltages (−5 V/+5 V) to the transfer electrodes 15 to discharge invalid charges out of the CCD diffusion layers 13, so that the dark current are suppressed as much as possible.

With respect to the CCD diffusion layers 13 out of which the invalid charges are discharged, the vertical transfer unit 16 fixes the transfer electrodes 15 to a negative voltage in succession so that the surface potentials of the CCD diffusion layers 13 approach the substrate potential. Due to such operations, holes gather near the first-plane sides of the CCD diffusion layers 13, thereby preventing the CCD diffusion layers 13 from surface depletion. Consequently, during the period of negative voltage application, the dark current that goes into the CCD diffusion layers 13 from the first-plane side can be suppressed greatly.

A synergistic effect of the functions makes it possible to suppress dark current sufficiently even in the cases of accumulating weak light for a long time.

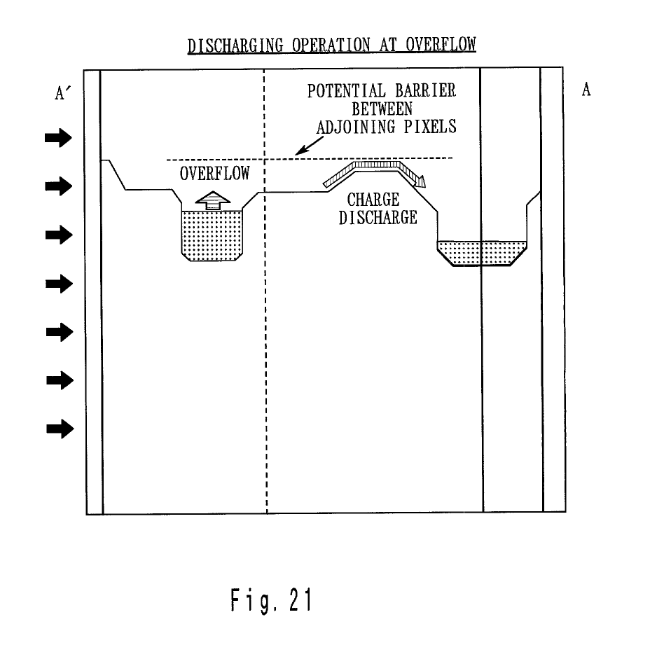

On the other hand, when illuminated with strong light, the potential wells in the charge accumulating units 17 are saturated, letting excessive charges flow out. Here, the potential barrier in the barrier region 519 is lower than the potential barriers between adjoining pixels. Therefore, the overflowing excessive charges preferentially flow into the CCD diffusion layers 13, as shown in FIG. 21. The excessive charges are discharged to exterior along with the dark current, by performing the above-described discharging operation by the CCD diffusion layers 13. As a result, the blooming phenomenon in the back-illuminated image sensor 511 is improved.

When the charge accumulating time is completed thus, the vertical transfer unit 16 applies a positive voltage of the order of 15 V to the transfer electrodes 15. It follows that the peak of the potential barrier created by the barrier region 519 is eliminated so that the signal charges in the charge accumulating units 17 are transported to the CCD diffusion layers 13.

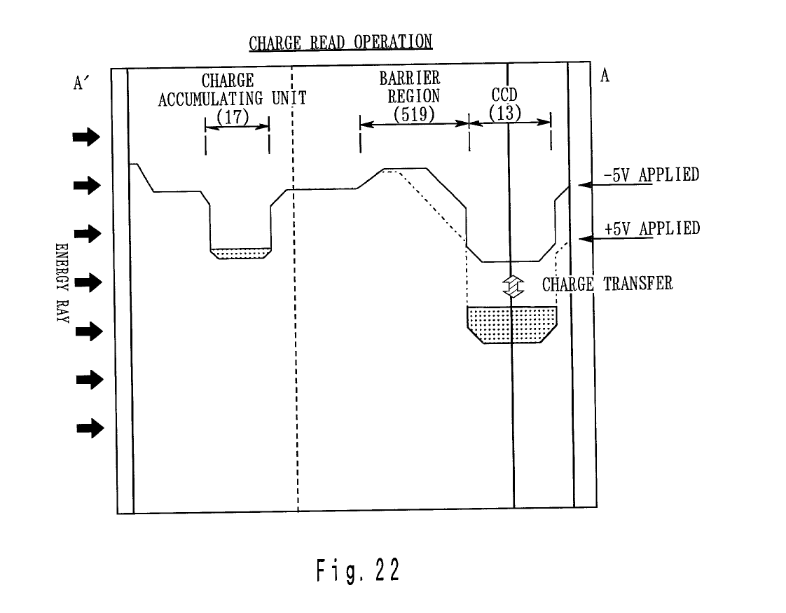

Subsequently, the vertical transfer unit 16, as shown in FIG. 22, successively applies transfer voltages of approximately ±5 V to the transfer electrodes 15 so that the signal charges in the CCD diffusion layers 13 are transferred in succession.

[Effects of the Third Embodiment]

In the third embodiment described above, the barrier region 519 is arranged between the charge accumulating units 17 and the CCD diffusion layers 13 to create a potential barrier peak. Therefore, the threshold voltage during the charge transportation from the charge accumulating units 17 to the CCD diffusion layers 13 is not so susceptible to the impurity concentration and thickness of the semiconductor base 12, and is controlled chiefly by the peak of the potential barrier (i.e., fabrication conditions of the barrier region 519). As a result, the characteristics of the image sensor 511 are not susceptible to the epitaxial growth conditions of the semiconductor base 12. This allows a sure improvement in the production yield of the image sensor 511.

In the above-described third embodiment, the charge accumulating units 17 are arranged on the second-plane side, opposite to the CCD diffusion layers 13. This substantially reduces the traveling distances of the signal charges on the second-plane side, allowing improvements to the efficiency of energy ray detection and the smear production. As a result, variations in the detection efficiency and in the smear production which result from the production variations of the semiconductor base 12 decrease. Therefore, the production yield of the image sensor 511 is also improved in that respect.

In particular, the above-mentioned improvements become more significant when the traveling distances of the signal charges on the second-plane side are longer (when the signal charges are generated at very shallow depth in the second plane as under ultraviolet rays or other short-wavelength energy rays).

Moreover, the peak of the potential barrier peak arising in the barrier region 519 provides an electrical partition between the charge accumulating units 17 and the CCD diffusion layers 13. This further reduces the possibility that the signal charges from the charge accumulating units 17 go into the CCD diffusion layers 13 during charge transfer, reliably negating the need for a mechanical shutter for shielding the second-plane side from light.

In particular, in the first fabrication method described above, the barrier region 519 is formed in contact with the CCD diffusion layers 13 (see FIG. 16B). In this case, the CCD diffusion layers 13 can be covered with a barrier region 519 of well shape so that they are isolated from the semiconductor base 12 with reliability. As a result, it becomes possible to substantially reduce the dark current and the like which go into the CCD diffusion layers 13 from the semiconductor-base-12 side.

In addition to such anti-dark-current measures, the third embodiment also provides anti-noise measures including the depletion prevention layer 18, the discharging of dark current, and the prevented surface depletion of the CCD diffusion layers 13. Since a synergistic effect of the measures greatly reduces noises that go into the sensed images, favorable imaging quality can be obtained even under severe conditions such as weak light detection.

Besides, in the third embodiment, the potential barrier in the barrier region 519 is set to be lower than the potential barriers between adjoining ones of the charge accumulating units 17. Accordingly, excessive charges overflowing the charge accumulating units 17 are preferentially discharged to the CCD diffusion layers 13. This reduces the possibility that excessive charges go into adjacent pixels, and thereby achieves the suppression of the blooming phenomenon.

Furthermore, in the first fabrication method described above, the barrier region 519 is formed in contact with the CCD diffusion layers 13. Therefore, it becomes possible to exercise sure potential control of the potential barrier peak of the barrier region 519, through the transfer electrodes 15 on the CCD diffusion layers 13.

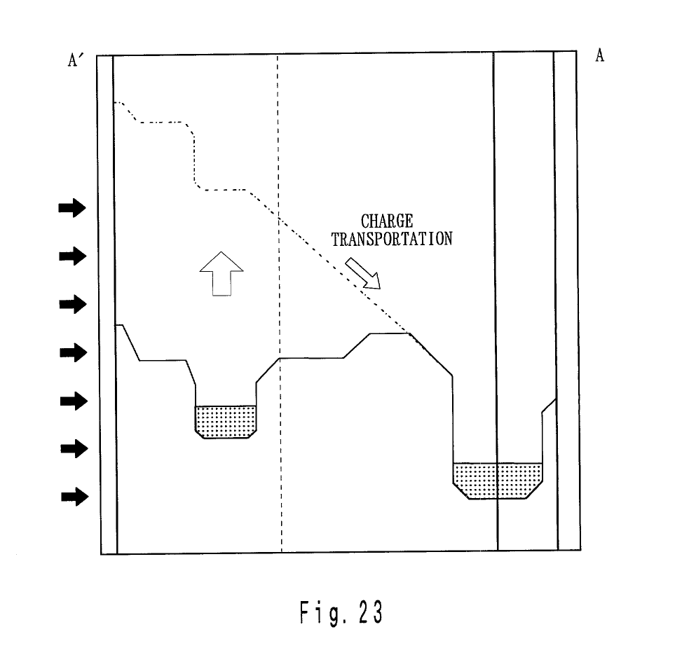

Note that in the third embodiment described above, the charge transportation from the charge accumulating units 17 to the CCD diffusion layers 13 is effected by applying voltages to the transfer electrodes 15. However, this is not restrictive. For example, as shown in FIG. 23, the charge transportation may be achieved by controlling the substrate potential.

Now, description will be given of another embodiment.

<Fourth Embodiment>

The fourth embodiment corresponds to the inventions set forth in claims 1-4 and 11-21.

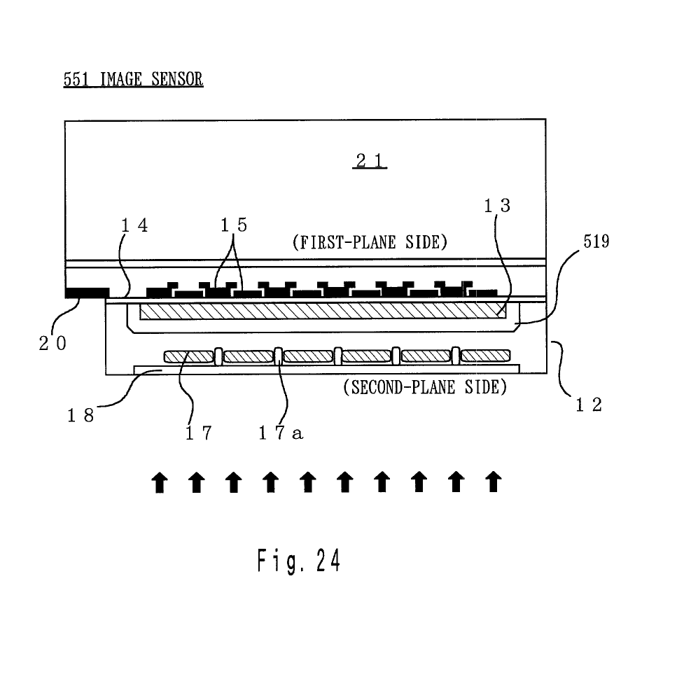

FIG. 24 is a diagram showing an image sensor 551 according to the fourth embodiment.

A constitutional feature of the fourth embodiment lies in that each pair of transfer electrodes 15 are provided in the charge transfer direction of the CCD diffusion layers 13 facing a single charge accumulating unit 17. Note that components common to those of the third embodiment (FIGS. 13 and 14) are shown in FIG. 24 with identical numerals attached thereto. Here, repetitive description thereof will be omitted.

The fabrication methods according to the fourth embodiment are identical to those of the third embodiment (FIGS. 16-19, FIG. 35) except that the charge accumulating units 17 have a different pixel pitch. Thus, description of the fabrication methods will be omitted here.

[Correspondences between the Present Invention and the Fourth Embodiment]

Hereinafter, description will be given of the correspondences between the present invention and the fourth embodiment. Incidentally, the correspondences are intended to provide an interpretation for reference purposes, not to limit the present invention in vain.

The following are the correspondences between the inventions set forth in claims 1-4 and the fourth embodiment. The semiconductor base corresponds to the semiconductor base 12. The charge transfer unit corresponds to the CCD diffusion layers 13, the gate oxide film 14, and the transfer electrodes 115. The charge accumulating units correspond to the charge accumulating units 17. The depletion prevention layer corresponds to the depletion prevention layer 18. The charge transport unit corresponds to “the configuration of transporting the signal charges in the charge accumulating units 17 to the CCD diffusion layers 13 under the voltage control of the transfer electrodes 15” in the vertical transfer unit 16.

The following are the correspondences between the inventions set forth in claims 11-15 and the fourth embodiment. The semiconductor base corresponds to the semiconductor base 12. The charge transfer unit corresponds to the CCD diffusion layers 13, the gate oxide film 14, the transfer electrodes 15, and the vertical transfer unit 16. The charge accumulating units correspond to the charge accumulating units 17. The charge transport unit corresponds to “the configuration of transporting the signal charges in the charge accumulating units 17 to the CCD diffusion layers 13 under the voltage control of the transfer electrodes 15” in the vertical transfer unit 16. The barrier region corresponds to the barrier region 519.

Then, the following are the correspondences between the inventions set forth in claims 19-21 and the fourth embodiment. In addition to the correspondences mentioned above, the charge transfer channel corresponds to the CCD diffusion layers 13. The transfer electrodes correspond to the transfer electrodes 115. The split transport unit corresponds to “the configuration of exercising voltage control of the transfer electrodes 15 to transport the signal charges in the charge accumulating units 17 to the CCD diffusion layers 13 at phase intervals” in the vertical transfer unit 16. The split transfer unit corresponds to “the configuration of supplying the transfer electrodes 15 with four-phase driving pulses for interlaced transfer of the signal charges” in the vertical transfer unit 16.

[Description of the Operation of the Fourth Embodiment]

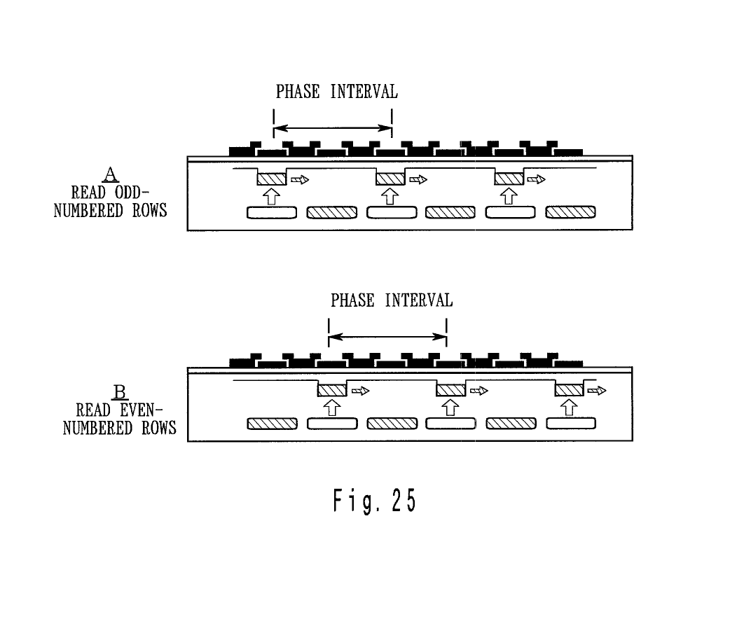

FIG. 25 is a diagram explaining a charge read operation of the image sensor 551 in the fourth embodiment.

Initially, as shown in FIG. 25A, the vertical transfer unit 16 applies a voltage of the order of +15 V to the transfer electrodes 15 facing charge accumulating units 17 in odd-numbered rows. It follows that the signal charges accumulated in the charge accumulating units 17 are transported to the CCD diffusion layers 13 at phase intervals (equivalent to intervals of four electrodes, because of the four-phase drive employed here). In this state, the vertical transfer unit 16 applies a four-phase driving pulse to the transfer electrodes 15 in succession, to transfer the signal charges in the CCD diffusion layers 13. The signal charges of the odd-numbered rows transferred thus are successively read out to exterior through the horizontal CCD unit 24. This completes the image read on the odd-numbered fields.

Next, as shown in FIG. 25B, the vertical transfer unit 16 applies the voltage of the order of +15 V to the transfer electrodes 15 facing charge accumulating units 17 in even-numbered rows. It follows that the signal charges accumulated in the charge accumulating units 17 are transported to the CCD diffusion layers 13 at regular phase intervals (equivalent to intervals of four electrodes, because of the four-phase drive employed here). In this state, the vertical transfer unit 16 applies a four-phase driving pulse to the transfer electrodes 15 in succession, to transfer the signal charges in the CCD diffusion layers 13. The signal charges of the even-numbered rows transferred thus are successively read out to exterior through the horizontal CCD unit 24. This completes the image read on the even-numbered fields.

[Effects of the Fourth Embodiment]

Due to the configuration described above, the fourth embodiment can offer the same effects as those obtained from the third embodiment.

Besides, the fourth embodiment allows the charge accumulating units 17 to be narrowed to a half in pixel row pitch as compared with the third embodiment. Therefore, the back-illuminated image sensor 551 can easily achieve higher resolutions.

Moreover, in the fourth embodiment, signal charges are transported from the charge accumulating units 17 to the CCD diffusion layers 13 at two-pixel intervals. This reduces the possibility that signal charges get mixed with each other during charge transportation, and thus allows the suppression of the smear production even at finer pixel pitches.

Note that in the fourth embodiment described above, two transfer electrodes 15 facing each single charge accumulating unit 17, are provided. However, the present invention is not limited thereto. For example, a single transfer electrode 15 may be arranged in each charge accumulating unit 17. Here, if the transfer electrodes 15 are intended for four-phase drive, one screen can be read out at four times. Moreover, if the transfer electrodes 15 are intended for three-phase drive, one screen can be read out at three times. Furthermore, if the transfer electrodes 15 are intended for two-phase drive, one screen can be read out at twice.

Now, description will be given of another embodiment.

<Fifth Embodiment>

The fifth embodiment corresponds to the inventions set forth in claims 1-4, 11-20, and 22.

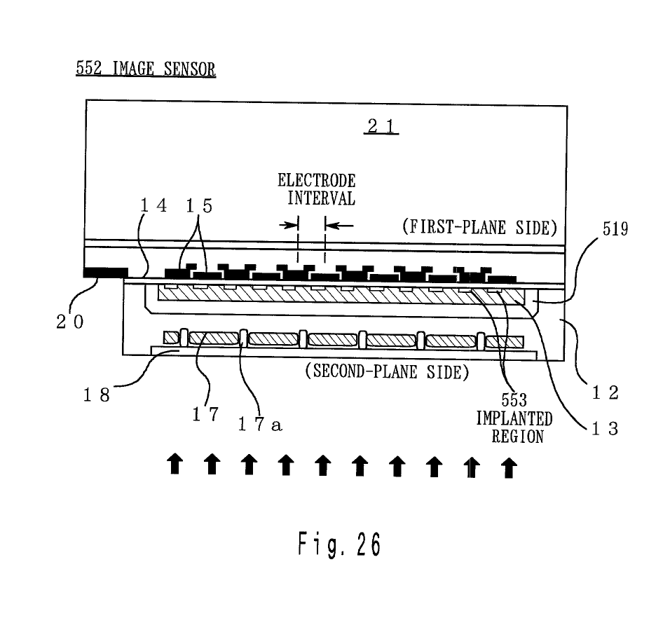

FIG. 26 is a diagram showing an image sensor 552 according to the fifth embodiment.

A constitutional feature of the fifth embodiment lies in that implanted regions 553 of the same conductive type as that of the semiconductor base 12 are arranged in the CCD diffusion layers 13, at electrode intervals of the transfer electrodes 15. The other constitution is identical to that of the fourth embodiment. Thus, description as to the constitution will be omitted here, while employing the same reference numbers as those in the fourth embodiment.

The fabrication methods according to the fifth embodiment are also identical to those of the third embodiment (FIGS. 16-19, 35) except that the charge accumulating units 17 have a different pixel pitch, and that the implanted regions 553 are formed by introducing impurities. Thus, description as to the fabrication methods will be also omitted here.

[Correspondences between the Present Invention and the Fifth Embodiment]

Hereinafter, description will be given of the correspondences between the present invention and the fifth embodiment.

The following are the correspondences between the inventions set forth in claims 1-4 and the fifth embodiment. The semiconductor base corresponds to the semiconductor base 12. The charge transfer unit corresponds to the CCD diffusion layers 13, the gate oxide film 14, and the transfer electrodes 15. The charge accumulating units correspond to the charge accumulating units 17. The depletion prevention layer corresponds to the depletion prevention layer 18. The charge transport unit corresponds to “the configuration of transporting the signal charges in the charge accumulating units 17 to the CCD diffusion layers 13 under the voltage control of the transfer electrodes 15” in the vertical transfer unit 16.

The following are the correspondences between the inventions set forth in claims 11-15 and the fifth embodiment. The semiconductor base corresponds to the semiconductor base 12. The charge transfer unit corresponds to the CCD diffusion layers 13, the gate oxide film 14, the transfer electrodes 15, and the vertical transfer unit 16. The charge accumulating units correspond to the charge accumulating units 17. The charge transport unit corresponds to “the configuration of transporting the signal charges in the charge accumulating units 17 to the CCD diffusion layers 13 under the voltage control of the transfer electrodes 115” in the vertical transfer unit 16. The barrier region corresponds to the barrier region 519.

The following are the correspondences between the inventions set forth in claims 19, 20, and 22 and the fifth embodiment. In addition to the correspondences mentioned above, the charge transfer channel corresponds to the CCD diffusion layers 13. The transfer electrodes correspond to the transfer electrodes 15. The variations in impurity concentration correspond to the variations in concentration caused by the implanted regions 553.

[Description of the Operation of the Fifth Embodiment]

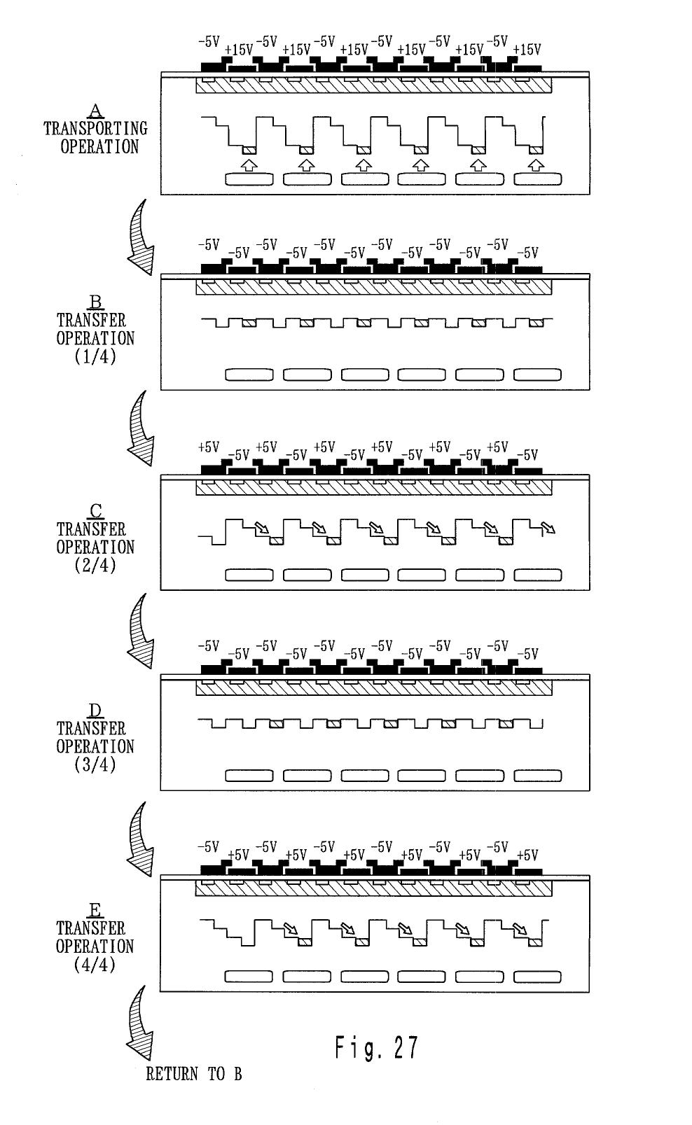

FIG. 27 is a diagram explaining a charge read operation of the image sensor 552 in the fifth embodiment.

Initially, as shown in FIG. 27A, the vertical transfer unit 16 applies a voltage of the order of +15 V to even-numbered transfer electrodes 15. The result is that one screenful of signal charges accumulated in the charge accumulating units 17 are collectively transported to the CCD diffusion layers 13.

Next, as shown in FIGS. 27B-E, the vertical transfer unit 16 applies a two-phase driving pulse to the transfer electrodes 15 in succession. Here, the implanted regions 553 produce periodic potential gradients in the CCD diffusion layers 13 (FIG. 27C, FIG. 27E). The signal charges move under the influence of the potential gradients; therefore, the signal charges travel in one direction. This results in two-phase progressive transfer.

The transferred signal charges in the even-numbered rows are successively read out to exterior through a horizontal CCD (not shown). This completes the image read for one screen.

[Effects of the Fifth Embodiment]

Due to the configuration described above, the fifth embodiment can offer the same effects as those obtained from the third embodiment.

Besides, the fifth embodiment allows the charge accumulating units 17 to be narrowed to a half in pixel row pitch as compared with the third embodiment. Therefore, the back-illuminated image sensor 552 can easily achieve higher resolutions.

Moreover, in the fifth embodiment, the provision of the variations in impurity concentration (here, the implanted regions 553) within the CCD diffusion layers 13 makes feasible the progressive transfer in two-phase drive.

In particular, the implanted regions 553 separate the signal charges from each other within the CCD diffusion layers 13. This reduces the possibility that signal charges get mixed with each other during charge transfer, and thereby allows a further reduction of the smear production.

Now, description will be given of another embodiment.

<Sixth Embodiment>

The sixth embodiment is of the exposure apparatuses corresponding to the inventions set forth in claims 1-9, 11-15, 19-32, and 43-46 (including alignment devices and measuring devices).

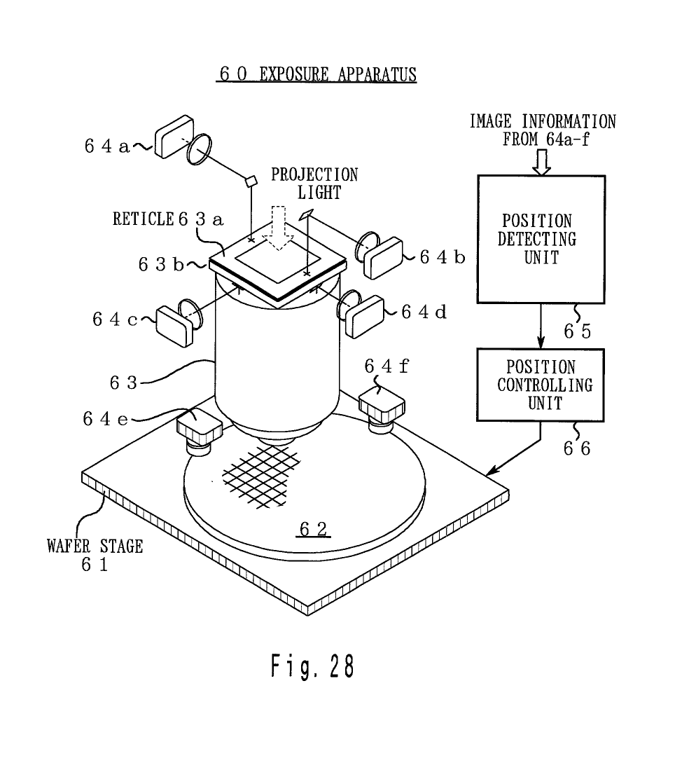

FIG. 28 is a diagram showing an exposure apparatus 60.

In FIG. 28, a semiconductor wafer 62, or a substrate to be exposed, is placed on a wafer stage 61. A reticle 63a and a reticle stage 63b are arranged above the semiconductor wafer 62 via an exposure unit 63, or a projection optical system.

Image sensors 64a and 64b of so-called TTR (through-the-reticle) type are arranged at positions where they sense marks on the reticle 63a and marks on the wafer-stage-61 side through the projection optical system and the reticle 63a.

In addition, image sensors 64c and 64d of so-called TTL (through-the-lens) type are arranged at positions where they sense the alignment marks on the wafer-stage-61 side through the projection optical system.

Besides, image sensors 64e and 64f of off-axis type are arranged at positions where they directly sense the alignment marks on the wafer-stage-61 side without the intervention of the projection optical system.

The image information sensed by the image sensors 64a-64f is supplied to a position detecting unit 65. The position detecting unit 65 detects the positions of the semiconductor wafer 62 and reference mark plates (not shown) according to the image information. A position controlling unit 66 controls the position of the wafer stage 61 according to the result of the position detection, thereby positioning the semiconductor wafer 62. Onto the semiconductor wafer 62 positioned thus, the exposure unit 63 projects a predetermined pattern of semiconductor circuit through the reticle 63a.

Such an exposure apparatus 60 incorporates image sensors according to any one of claims 1-9, 11-15, and 19-22 (for example, the above-described image sensors 11,51, 511, 551, 552) as the image sensors 64a-f.

Therefore, a reduction in the wavelength of the illuminating light for sensing is facilitated, which makes it possible to sense finer alignment marks with higher imaging quality. Moreover, it becomes possible to obtain favorable sensed images with smaller variations from the image sensors 64a-f.

This consequently improves the measuring accuracy of the position detection, allowing the exposure apparatus 60 to be further improved in positioning accuracy.

Now, description will be given of another embodiment.

<Seventh Embodiment>

The seventh embodiment is of the exposure apparatuses corresponding to the inventions set forth in claims 1-9, 11-15, 19-22, and 33-46 (including aberration measuring devices and measuring devices).

The seventh embodiment shows an example where an image sensor according to any one of claims 1-9, 11-15, and 19-22 (for example, the image sensor 11, 51, 511, 551, or 552) is used to measure a target optical system (a projection optical system PL, in this example) for optical characteristics (wave aberration information such as a coma aberration, an astigmatic aberration, and a spherical aberration).

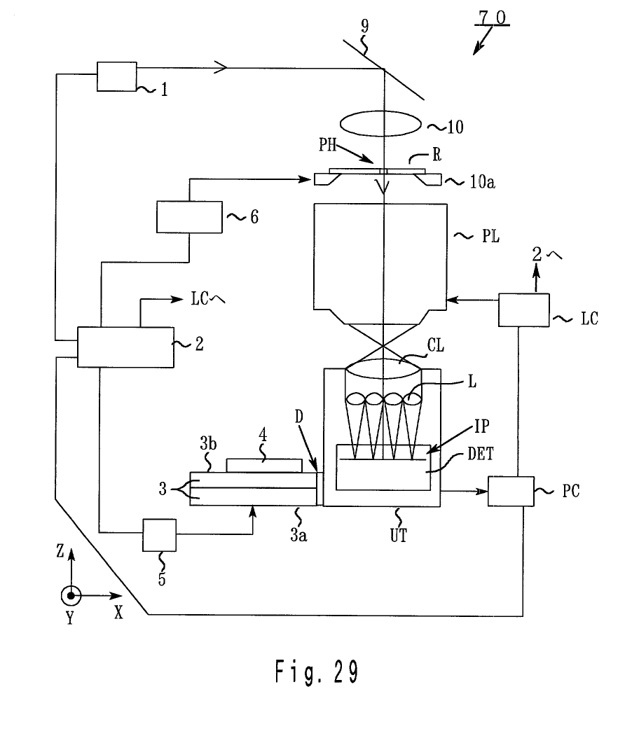

FIG. 29 is a diagram showing an overview of an exposure apparatus 70 according to the seventh embodiment. Exposure light produced by a light source 1 passes a mirror 9 and a condenser lens 10 to illuminate a reticle (mask) R. The reticle R is placed on a reticle stage 10a. The reticle stage 10a is controlled by a reticle stage controlling unit 6.

A wafer holder 4 is arranged on a wafer stage 3 (an XY stage 3a and a Z/leveling stage 3b) so that a wafer W (not shown) is chucked on the wafer holder 4. The wafer stage 3 is drive-controlled and position-controlled by a wafer stage controlling unit 5.

A main control unit 2 is electrically connected to the light source 1, the reticle stage controlling unit 6, and the wafer stage controlling unit 5, and is configured to exercise centralized control thereof. The main control unit 2 is also electrically connected to a lens controlling unit LC (to be described later) for controlling a projection optical system PL, and to a processing unit PC (to be described later) for calculating the aberrations of the optical system according to the measurements from an aberration measuring unit UT to be described later. The main control unit 2 also exercises centralized control of the units.

The aberration measuring unit UT is detachably attached to a side of the wafer stage 3 via a detachable mechanism D. The aberration measuring unit UT comprises a collimator lens CL, a 2D lens array having a plurality of lens elements L put in a two-dimensional arrangement, and a condensing position detecting unit DET. The condensing position detecting unit DET contains one of the above-described image sensors 11, 51, 511, 551, and 552. Pencils of light past the plurality of lens elements are condensed onto the imaging plane IP of the image sensor.

Note that when the aberration measuring unit UT is mechanically connected to the exposure apparatus 70 (the side of the stage 3) via the detachable mechanism D, the aberration measuring unit UT is also electrically connected to the processing unit PC so as to be capable of communicating with each other.

Incidentally, in the present embodiment, the processing unit PC is arranged on the side of exposure apparatus 70. Nevertheless, the processing unit PC is not limited thereto, and may be arranged inside the aberration measuring unit UT so that the processing unit PC becomes capable of communicating with the exposure apparatus 70 when the unit UT is connected to the exposure apparatus 70.

[Description of the Operation of the Seventh Embodiment]

Next, description will be given of the procedures for performing the wave aberration measurement and the aberration correction of the projection optical system PL.

In measuring the wavefront in the projection optical system PL, light having a spherical wavefront, as a pencil of light for wave aberration measurement, is launched into the projection optical system PL. The spherical-wave light can be produced by mounting a reticle R (FIG. 29) with a pinhole pattern PH onto the reticle position and illuminating the same with light from the light source 1. This (the pinhole-patterned reticle) is, however, not restrictive. The pinhole may be formed in the reticle stage 10a and illuminated. Otherwise, a point light source may be used. Alternatively, a region for transmitting the light from the light source 1 with diffusion (so-called lemon-skinned) may be arranged on the reticle R or the reticle stage 10a so that the light past the lemon-skinned region is used as the light source for wave aberration measurement. In this connection, the reticle stage 10a and the reticle R desirably have the above-described pinhole or lemon-skinned region. It is even preferable that a plurality of pinholes in different sizes is provided so that the pinholes can be appropriately selected according to the purposes of the measurement.

Incidentally, when the light for wave aberration measurement is produced by using the reticle R, the reticle R constitutes an aberration measuring optical system. When the light is produced by using the reticle stage 10a, the reticle stage 10a constitutes the aberration measuring optical system.

The spherical-wave light formed thus is incident on the projection optical system PL. The wafer stage controlling unit 5 drives and controls the wafer stage 3 so that the transmitted wavefront from the projection optical system PL is incident on the aberration measuring unit UT which is detachably attached to the side of the stage 3 via the detachable mechanism D.

The light past the projection optical system PL is converted into parallel light by the collimator lens CL. The light is then incident on the 2D lens array having small lenses L in a two-dimensional arrangement. If the target wavefront of the incident light has a deviation from an ideal wavefront, i.e., the wavefront for situations where the projection optical system has no aberration, the deviation appears as positional shifts of the condensing points. The processing unit PC calculates the wave aberration in the projection optical system PL according to the positional shifts of the condensing points of the individual lenses L in the 2D lens array.

Thus, at a point on the image-forming plane of the projection optical system PL, the target wavefront can be measured for positional shifts of the individual measurement points with respect to the condensing points of an ideal wavefront, to determine the spherical aberration and the astigmatic difference of the projection optical system PL.

Besides, the wafer stage controlling unit 5 drives the wafer stage 3 so that the aberration measuring unit UT moves to a plurality of points on the image-forming plane of the projection optical system PL. Then, at each of the plurality of points on the image-forming plane of the projection optical system PL, the target wavefront can be measured for positional shifts of the individual measurement points with resect to the condensing points of the ideal wavefront. The coma aberration, field curvature, distortion, and astigmatic aberration of the projection optical system PL can be determined from the measurements.

Then, the obtained aberration information on the projection optical system PL is fed back to the lens controlling unit LC. Based on the aberration information, the lens controlling unit LC adjusts the gaps between the lens elements constituting the projection optical system PL and the pressure of the air in the gaps, so that the aberrations of the wavefront past the projection optical system PL are confined to predetermined ranges.

[Effects of the Seventh Embodiment]

In the seventh embodiment, the aberration measuring unit UT contains one of the image sensors 11, 51, 511, 551, and 552. Accordingly, the image sensor can provide favorable sensed images for aberration measurement, allowing a further improvement in the aberration correction accuracy of the exposure apparatus 70.

Incidentally, the aberration measuring unit UT may be detachably attached to the wafer holder 4 or the wafer stage 3. Otherwise, it may be incorporated into the wafer stage 3, or arranged in the vicinity of the wafer stage 3.

The condensing point detecting unit DET and the wafer stage 3 are preferably increased in measuring resolution and positioning accuracy, respectively, to improve the aberration measuring accuracy of the projection optical system PL. For example, when the condensing point detecting unit DET has a detecting resolution of 10-20 μm, an exposure apparatus for 5- by 5-mm exposure preferably controls the wafer stage 3 by 1-mm pitches.

In the present embodiment, the aberration measuring unit UT is detachably attached to the wafer stage 3. As for the detachable mechanism, notched portions may be provided in the wafer stage 3 while engaging portions for engaging with the notched portions are arranged on the measuring device for the sake of detachable attachment. Moreover, in the cases of detachably attaching the aberration measuring unit UT to the wafer stage 3, not the entirety but part of the aberration measuring unit UT, such as the collimator lens CL and the lenses L, may be rendered detachable so that the detecting unit DET is fixed to the wafer stage 3. On the contrary, the collimator lens CL and the lenses L, for example, may be fixed to the wafer stage 3 while the detecting unit DET is rendered detachable. Moreover, all of the collimator lenses CL, the lenses L, and the detecting unit DET may be fixed to the wafer stage 3.

In the present embodiment, the projection optical system PL is measured for wave aberration as incorporated in the exposure apparatus. However, it may be measured before incorporating into the exposure apparatus. The wave aberration can be measured at any timings such as at every wafer replacement, every reticle replacement, and predetermined timing. Any other timing may also be employed. Even in those cases, the measuring accuracy can be selected as described above.

The present embodiment has dealt with the case where the projection optical system PL mounted on the exposure apparatus 70 is measured for aberrations. However, the present invention is not limited thereto. It is understood that any of the image sensors 11, 51, 511, 551, and 552 may be used for aberration measurement of a variety of optical systems.

<Eighth Embodiment>

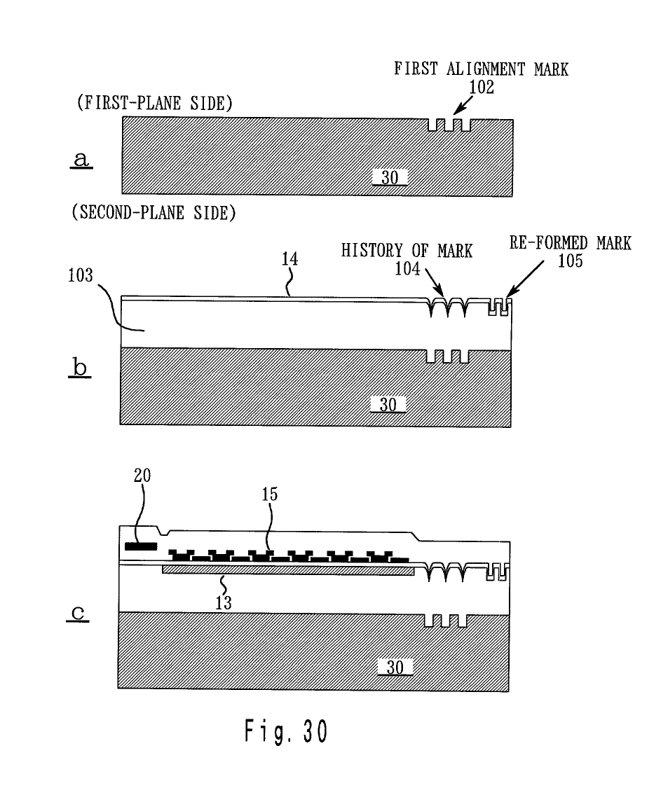

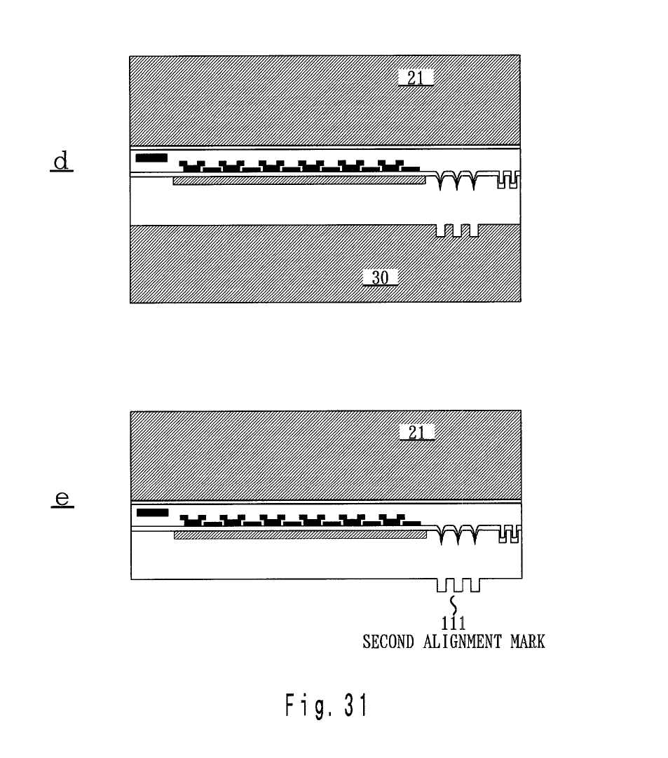

The eighth embodiment refers to a method of fabricating the image sensor 11 corresponding to the inventions set forth in claims 1-4, 10, 47, 49, and 50. FIGS. 30 and 31 are diagrams showing the steps of the fabrication method. Hereinafter, the individual steps of the present fabrication method will be described with reference to FIGS. 30 and 31.

For a start, a first alignment mark 102 is formed in the first-plane side of a P⁺-type substrate 30 having a concentration of the order of 1E18/cm³ (corresponding to the mark forming step in claims 47, 49, and 50). The first alignment mark 102 is concave steps formed in silicon by etching or the like. FIG. 30a shows the state described above. Incidentally, the first alignment mark may be of convex shape. For example, a rather thick oxide film can be formed on the P⁺-type substrate 30 so that the oxide film is partly removed to leave convex steps.

Note that the substrate 30 (silicon substrate) may be any heavily doped impurity substrate including an N⁺-type substrate. For example, Sb (antimony) is preferably used as the N-type impurities in this substrate 30. Moreover, Sb preferably has a concentration rate greater than or equal to 1E18/cm³. The reason why Sb is preferred here is that it can suppress auto doping in the subsequent step (the vapor phase growth of a P-type epitaxial layer 103). The auto doping has an enormous effect on the shape of the first alignment mark 102 (history 104 to be described later). In some conditions, the first alignment mark 102 (history 104) might be distorted so greatly that it fails to function as a mark. The above-mentioned Sb, however, has a property against the auto doping. Thus, selecting Sb as impurities in the substrate 30 allows the first alignment mark 102 (history 104) to be maintained in a favorable shape.

Next, a P-type epitaxial layer 103 of 1E15/cm³ in concentration is formed on the first-plane side of the P⁺-type substrate 30, in a thickness of around 10 μm (corresponding to the base forming step in claims 47, 49, and 50). The P-type epitaxial layer 103 is to be the base portion of the device.

Here, the steps of the first alignment mark 102 appear as a history 104 on the first-plane side of the P-type epitaxial layer 103. By using the history 104 as a positional reference, the re-formation of a mark is performed to make a re-formed mark 105 anew in the first-plane side of the P-type epitaxial layer 103 (corresponding to the re-forming step in claim 49). FIG. 30b shows the state described above.

Subsequently, with the re-formed mark 105 as the positional reference, a device structure including channel isolations, a diffusion region, CCD diffusion layers 13, a gate oxide film 14, transfer electrodes 15, pixel-reading gate electrodes, AL wiring, bonding pads 20, and a passivation film is formed on the first-plane side of the P-type epitaxial layer 103 (corresponding to the first-plane side processing step in claim 47, and the processing step in claim 49). FIG. 30c shows the state described above.

Next, the first-plane side is planarized based on SOG (Spin On Glass) or other methods. If necessary, CMP (Chemical Mechanical Polishing), mechanical polishing, and the like are performed for thinning. Thereafter, a lightly doped silicon substrate to be a support substrate 21 is pasted on the first-plane side with a silicon-type adhesive or the like. FIG. 31d shows the state described above.

Here, in a solution formulated to 1:3:8 in hydrofluoric: acid (50%):nitric acid:acetic acid, the P⁺-type substrate 30 is etched for removal. This kind of solution is higher in P⁺-type etching rate than in P⁻-type etching rate. The difference in etching rate is utilized to stop the etching. Here, a second alignment mark 111, or the inverted mark of the first alignment mark, appears on the second-plane side of the P-type epitaxial layer 103 (corresponding to the thinning step in claim 10, and the removing step in claims 47 and 50). In order to reduce the etching time, the P⁺-type substrate 30 may be previously thinned at the second-plane side based on polishing or other methods. FIG. 31e shows the state described above.

Next, by using the second alignment mark 111 as a positional reference, a device structure including charge accumulating units 17 and a depletion prevention layer 18 is formed on the second-plane side of the P-type epitaxial layer 103, thereby completing the image sensor 11 as shown in FIG. 2 (corresponding to the accumulating unit forming step and the layer forming step in claim 10, the second-plane side processing step in claim 47, and the processing step in claim 50).

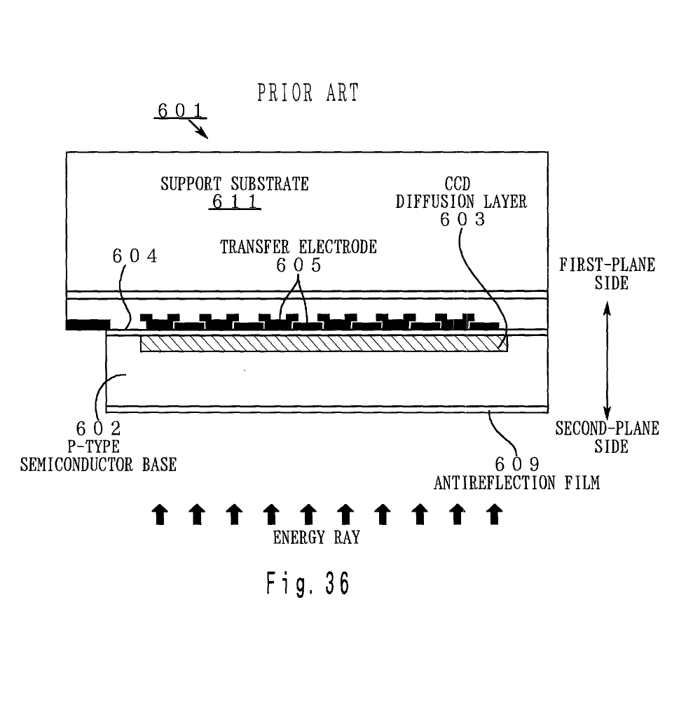

Incidentally, in the state shown in FIG. 31e, a backside processing layer, pad openings, and the like can also be formed by using the second alignment mark 111 as a positional reference, to form the conventional back-illuminated image sensor as shown in FIG. 36.

As has been described above, in the fabrication method of the eighth embodiment, the positional reference on either surface (the re-formed mark 105, the second alignment mark 111) is formed in accordance with the first alignment mark 102. Therefore, precise position matching can be achieved between the two-sided structures, which allows precise alignment of the charge accumulating units 17, the CCD diffusion layers 13, the transfer electrodes 15, the opening holes for the bonding pads 20, and so on. As a result, it becomes possible to fabricate image sensors 11 of higher performance. Moreover, higher-resolution (or finer) image sensors 11 are significantly improved in production yield.

In particular, the fabrication method excludes any steps where the device structure on one side is formed while alignment is achieved with the alignment mark on the opposite side. This makes it possible to fabricate the image sensor 11 without using a conventional double side aligner or infrared aligner.

Now, description will be given of another embodiment.

<Ninth Embodiment>

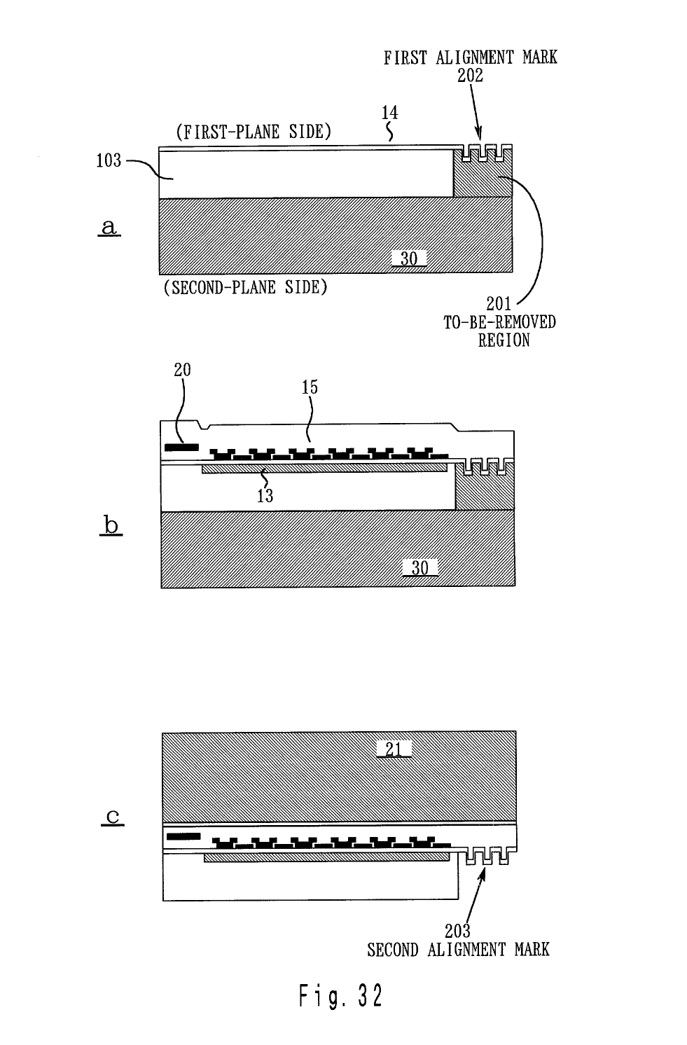

The ninth embodiment refers to a method of fabricating the image sensor 11 corresponding to the inventions set forth in claims 1-4, 10, and 48. FIG. 32 is a diagram showing the steps of the fabrication method. Hereinafter, the present fabrication method will be described with reference to FIG. 32.

Initially, a P-type epitaxial layer 103 of 1E15/cm³ in concentration is formed on the first-plane side of a P⁺-type substrate 30, in a thickness of approximately 10 um (corresponding to the base forming step in claim 48).

During the step of forming the P-type epitaxial layer 103 or after the formation, a heavily doped P⁺-type region that reaches the P⁺-type substrate is formed in part of the P-type epitaxial layer 103 according to such methods as ion implantation and thermal diffusion. This forms a to-be-removed region 201 (corresponding to the to-be-removed region forming step in claim 48).

A first alignment mark 202 is formed in the first-plane side of the to-be-removed region 201 (corresponding to the mark forming step in claim 48). FIG. 32a shows the state described above.

Note that the to-be-removed region 201 may be any heavily doped impurity region including an N⁺-type impurity region. In particular, when the vapor phase growth of the P-type epitaxial layer 103 continues after the formation of the first alignment mark 202, it is preferable to select Sb (antimony) as the N-type impurities in the to-be-removed region 201. In such a case, Sb preferably has a concentration rate greater than or equal to 1E18/cm³. The reason why Sb is preferred here is that it can suppress auto doping in the vapor phase growth of the P-type epitaxial layer 103. The auto doping has an enormous effect on the shapes of the first alignment mark 202. In some conditions, the first alignment mark 202 might be distorted so greatly that it fails to function as a mark. The above-mentioned Sb, however, has a property against the auto doping. Thus, selecting Sb as impurities in the to-be-removed region 201 allows the first alignment mark 202 to be maintained in a favorable shape. As a result, a second alignment mark 203 to be described later can also be formed in a favorable shape.

By using the first alignment mark 202 as a positional reference, the structure on the first-plane side of the image sensor 11 is formed (corresponding to the first-plane side processing step in claim 48).

During the process described above, a layer adequate for forming an inverted mark is formed over the first alignment mark (corresponding to the layer forming step in claim 48). FIG. 32b shows the state described above.

Next, the first-plane side is planarized, and a support substrate 21 is pasted thereon. In this state, the P⁺-type substrate 30 and the to-be-removed region 201 are etched for removal (corresponding to the thinning step in claim 10). Here, a second alignment mark 203, or the inverted mark of the first alignment mark 202, appears on a trace of the removed to-be-removed region 201 (corresponding to the removing step in claim 48). FIG. 32c shows the state described above.

Next, with the second alignment mark 203 as the positional reference, a device structure (including charge accumulating units 17 and a depletion prevention layer 18) is formed on the second-plane side of the P-type epitaxial layer 103, thereby completing the image sensor 11 as shown in FIG. 2 (corresponding to the accumulating unit forming step and the layer forming step in claim 10; also corresponding to the second-plane side processing step in claim 48).

Incidentally, in the state shown in FIG. 32c, a backside processing layer, pad openings, and the like can also be formed by using the second alignment mark 203 as a positional reference, to form the conventional back-illuminated image sensor as shown in FIG. 36.

As has been described above, in the fabrication method of the ninth embodiment, the second alignment mark 203 on the second-plane side is formed to be molded from the first alignment mark 202 in the first-plane side. Therefore, both alignment marks come into precise position matching, thereby making it possible to achieve precise alignment of the charge accumulating units 17, the CCD diffusion layers 13, the transfer electrodes 15, the opening holes for the bonding pads 20, and others shown in FIG. 2. As a result, it becomes possible to fabricate image sensors 11 of higher performance. Moreover, higher-resolution (or finer) image sensors 11 are significantly improved in production yield.

In particular, the fabrication method excludes any steps where the device structure on one side is formed while alignment is achieved with the alignment mark on the opposite side. This makes it possible to fabricate the image sensor 11 without using a conventional double side aligner or infrared aligner.

Now, description will be given of another embodiment.

<Tenth Embodiment>

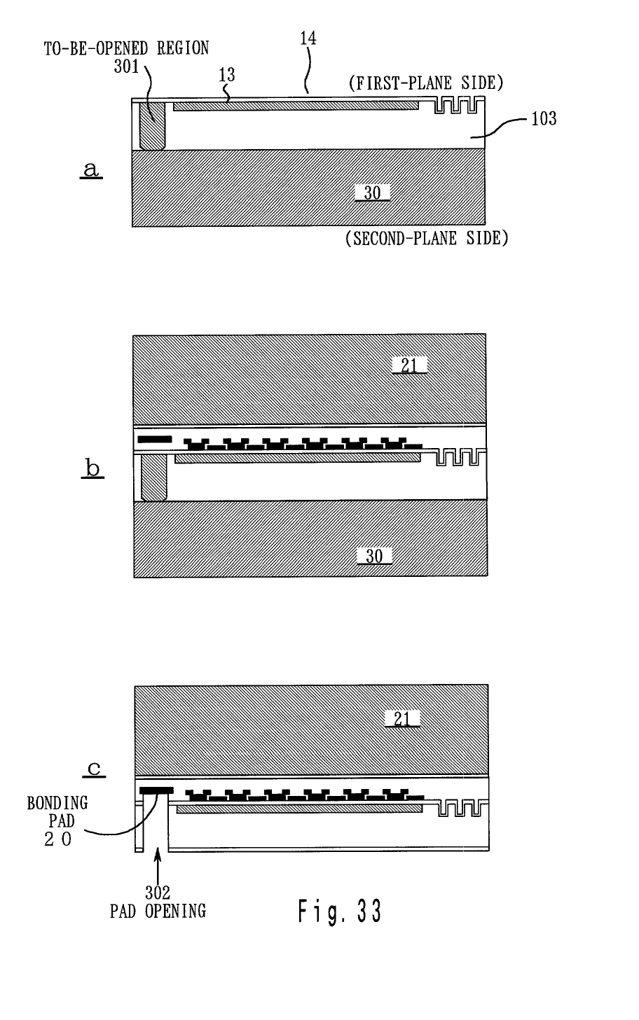

The tenth embodiment refers to a method of fabricating the image sensor 11 corresponding to the inventions set forth in claims 1-4, 10, and 52. FIG. 33 is a diagram showing the steps of the fabrication method.

For a start, a P-type epitaxial layer 103 is formed on the first-plane side of a P⁺-type substrate 30 (corresponding to the base forming step in claim 52).

Next, ion implantation, thermal diffusion, or other processing is applied to the P-type epitaxial layer 103 from the first-plane side, so that heavily doped P⁺-type regions that reach the P⁺-type substrate are formed in areas where openings for the bonding pads 20 and the like are to be made. The P⁺-type regions are to be the to-be-opened regions 301 (corresponding to the to-be-opened region forming step in claim 52). FIG. 33a shows the state described above.

The structure on the first-plane side is formed as in the foregoing embodiment. Then, the first-plane side is planarized, and a support substrate 21 is pasted thereon. FIG. 33b shows the state described above.

Next, the P⁺-type substrate 30 and the to-be-opened regions 301 are etched for removal (corresponding to the thinning step in claim 10). Here, pad openings 302 and the like appear as traces of the removed to-be-opened regions 301 (corresponding to the removing step in claim 52). FIG. 33c shows the state described above.

Next, a device structure (including charge accumulating units 17 and a depletion prevention layer 18) is formed on the second-plane side to complete the image sensor 11 as shown in FIG. 2 (corresponding to the accumulating unit forming step and the layer forming step in claim 10).

As has been described above, in the fabrication method of the tenth embodiment, the to-be-opened areas in the second-plane side are positioned from the first-plane side.

Accordingly, opening holes in proper alignment with the structure on the first-plane side (for example, the bonding pads 20) can be formed in the second-plane side.

<Supplemental Remarks on the Embodiments>

In the embodiments described above, the vertical transfer unit 16 (the invalid charge discharging unit) may clear up the unnecessary charges in the charge accumulating units 17 (image lags and dark current having been accumulated before the exposure time) through the CCD diffusion layers 13 at the start of the charge accumulating. Such an operation allows a further improvement in image quality. Besides, adjusting the length of the accumulating time in this manner can also provide an electronic shutter function.

Moreover, in the above-described embodiments, both the transfer electrodes 15 and the substrate potential may be controlled in order to transport the charges in the charge accumulating units 17 to the CCD diffusion layers 13. Such an operation makes it possible to perform sure charge transportation even with charge accumulating units 17 having a greater saturation charge amount.

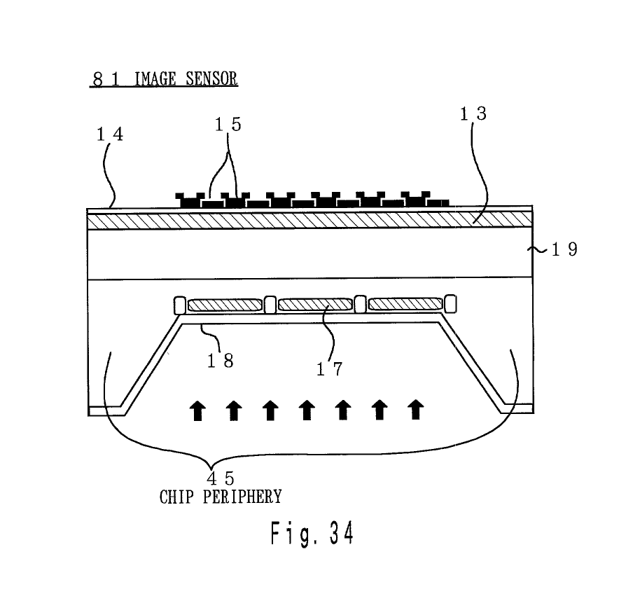

Furthermore, in the above-described embodiments, the support substrate 21 is pasted on to reinforce the chip. However, this is not restrictive. For example, as in an image sensor 81 shown in FIG. 34, at the time of etching, a chip periphery 45 may be left unetched, thereby increasing the mechanical strength of the chip.

Moreover, in the above-described embodiments, the semiconductor base 12 is thinned by chemical etching. However, this is not restrictive. For example, the thinning may be performed based on such methods as mechanical polishing and anisotropic etching.

Furthermore, in the above-described embodiments, P-type is the first conductive type and N-type is the second conductive type. However, this is not restrictive. N-type can be the first conductive type and P-type can be the second.

Note that the above-described exposure apparatuses may also be realized as a scanning exposure apparatus in which the reticle and the substrate are synchronously moved for reticle pattern exposure (for example, U.S. Pat. No. 5,473,410).

Besides, the above-described exposure apparatuses may be realized as an exposure apparatus of step-and-repeat type in which the reticle and the substrate are kept stationary for reticle pattern exposure, and the substrate is successively moved stepwise.

The above-described exposure apparatuses may also be realized as a proximity exposure apparatus in which no projection optical system is used, and the reticle and the substrate are put into close contact for reticle pattern exposure.

Moreover, the applications of the above-described exposure apparatuses are not limited to semiconductor fabrications. For example, it is also possible to realize an exposure apparatus for use in liquid crystal for exposing a liquid crystal display element pattern on a glass plate, and an exposure apparatus for fabricating thin film magnetic heads. For their light sources, the above-described exposure apparatuses may use g-rays (436 nm), i-rays (365 nm), KrF excimer lasers (248 nm), ArF excimer lasers (193 nm), F₂ lasers (157 nm), metal vapor lasers, and harmonic components of YAG lasers. Additionally, charged particle beams such as X-rays and electron beams may be used. For example, in the cases of electron beams, the electron gun may use thermionic lanthanum hexaboride (LaB₆) and tantalum (Ta).

The exposure apparatuses may have any projection magnifications, not only reducing but also unmagnifying and enlarging.

As for the projection optical system, such materials as quartz and fluorite which transmit far-ultraviolet rays are used for the glass material in the cases of using excimer lasers and other far-ultraviolet rays. In the cases of F₂ lasers or X-rays, a catadioptric or dioptric system is employed (the reticle is also of dioptric type). In the cases of electron beams, an electron optical system comprising electron lenses and deflectors can be used as the optical system. Incidentally, it is understood that the optical paths for electron beams to pass through should be kept in a vacuum.

Note that the image sensors according to the present invention are not limited to the exposure apparatuses in application, and are also applicable to general systems that comprise image sensors.

Moreover, the device fabrication methods according to the present invention are applicable to any method of forming device structures on both sides.

The invention is not limited to the above embodiments and various modifications may be made without departing fromt the spirit and the scope of the invention. Any improvement may be made in part or all of the components.

What is claimed is:

1. A back-illuminated image sensor comprising:
a semiconductor base of a first conductive type;
a plurality of charge accumulating units of a second conductive type different from said first conductive type, formed on a second-plane side which is the backside of a first plane of said semiconductor base, said charge accumulating units which accumulate, on a pixel-by-pixel basis, signal charges generated by an energy ray incident from the second-plane side;
a charge transfer unit formed on the first-plane side of said semiconductor base facing said charge accumulating units, the charge transfer unit which transfers said signal charges to be read;
a charge transport unit which transports said signal charges accumulated in said charge accumulating units to said charge transfer unit; and
a depletion prevention layer formed closer to said second-plane side than said charge accumulating units, the depletion prevention layer which prevents a depletion region around said charge accumulating units from reaching said second plane.

2. An image sensor according to claim 1, wherein said depletion prevention layer is of said first conductive type.

3. An image sensor according to claim 2, wherein said depletion prevention layer has impurity distribution that allows said energy ray to pass through and impurity concentration rate that prevents said depletion region from reaching said second plane.

4. An image sensor according to claim 2, wherein said charge accumulating units are fully depleted at completion of charge transportation.

5. A back-illuminated image sensor comprising:
a semiconductor base of a first conductive type;
a plurality of charge accumulating units of a second conductive type different from said first conductive type, formed on a second-plane side which is the backside of a first plane of said semiconductor base, said charge accumulating units which accumulate, on a pixel-by-pixel basis, signal charges generated by an energy ray incident from the second-plane side;
a charge transfer unit formed on the first-plane side of said semiconductor base facing said charge accumulating units, the charge transfer unit which transfers said signal charges to be read;
a charge transport unit which transports said signal charges accumulated in said charge accumulating units to said charge transfer unit; and
an invalid charge discharging unit which drives said charge transfer unit to discharge an invalid charge while said charge accumulating units accumulate said signal charges.

6. A back-illuminated image sensor comprising:
a semiconductor base of a first conductive type;
a plurality of charge accumulating units of a second conductive type different from said first conductive type, formed on a second-plane side which is the backside of a first plane of said semiconductor base, said charge accumulating units which accumulate, on a pixel-by-pixel basis, signal charges generated by an energy ray incident from the second-plane side;
a charge transfer unit formed on the first-plane side of said semiconductor base facing said charge accumulating units, the charge transfer unit which transfers said signal charges to be read;
a charge transport unit which transports said signal charges accumulated in said charge accumulating units to said charge transfer unit; and
a dark current suppressing unit which approximates a potential of the first-plane side of said charge transfer unit to a substrate potential to suppress dark current flowing in from said first-plane side, at least during a predetermined period while said charge accumulating units accumulate said signal charges.

7. A back-illuminated image sensor comprising:
a semiconductor base of a first conductive type;
a plurality of charge accumulating units of a second conductive type different from said first conductive type, formed on a second-plane side which is the backside of a first plane of said semiconductor base, said charge accumulating units which accumulate, on a pixel-by-pixel basis, signal charges generated by an energy ray incident from the second-plane side;
a charge transfer unit formed on the first-plane side of said semiconductor base facing said charge accumulating units, the charge transfer unit which transfers said signal charges to be read;
a charge transport unit which transports said signal charges accumulated in said charge accumulating units to said charge transfer unit; and
an excessive charge discharging unit which overflows an excessive charge into said charge transfer unit and drives said charge transfer unit to discharge said excessive charge, said excessive charge occurring due to exceeding a saturation charge amount of said charge accumulating units.

8. An image sensor comprising:
a semiconductor base of a first conductive type;
a plurality of charge accumulating units of a second conductive type different from said first conductive type, formed on a second-plane side which is the backside of a first plane of said semiconductor base, said charge accumulating units which accumulate, on a pixel-by-pixel basis, signal charges generated by an energy ray incident from the second-plane side;
a charge transfer unit formed on the first-plane side of said semiconductor base facing said charge accumulating units, the charge transfer unit which transfers said signal charges to be read; and
a charge transport unit which transports said signal charges accumulated in said charge accumulating units to said charge transfer unit, and wherein
said charge transport unit applies a voltage to said semiconductor base to control said charge accumulating units in potential, whereby transports said signal charges in said charge accumulating units to said charge transfer unit.

9. An image sensor according to claim 8, wherein said semiconductor base has a well structure surrounded by a semiconductor region of said second conductive type.

10. A method of fabricating a back-illuminated image sensor, comprising:
a thinning step of thinning a semiconductor base of a first conductive type;
an accumulating unit forming step of forming, on one plane side of said semiconductor base thinned, a plurality of charge accumulating units of a second conductive type different from said first conductive type; and
a layer forming step of forming, on the one plane side of said semiconductor base thinned, a depletion prevention layer of said first conductive type for preventing a surface deletion resulting from said charge accumulating units.

11. A back-illuminated image sensor comprising:
a semiconductor base of a first conductive type;
a plurality of charge accumulating units of a second conductive type different from said first conductive type, formed on a second-plane side which is the backside of a first plane of said semiconductor base, said charge accumulating units which accumulate, on a pixel-by-pixel basis, signal charges generated by an energy ray incident from the second-plane side;
a charge transfer unit formed on the first-plane side of said semiconductor base facing said charge accumulating units, the charge transfer unit which transfers said signal charges to be read;
a charge transport unit which transports said signal charges accumulated in said charge accumulating units to said charge transfer unit; and
a barrier region provided on at least a part of transport paths of said signal charges formed between said charge accumulating units and said charge transfer unit, the barrier region which creates a peak of a potential barrier to block progress of said signal charges when no charge is to be transported and ensures full transportation of said signal charges by eliminating the peak of said potential barrier by said charge transport unit when a charge is transported.

12. An image sensor according to claim 11, wherein said barrier region is formed by introducing impurities of said first conductive type into said semiconductor base.

13. An image sensor according to claim 12, wherein a concentration rate of said impurities introduced into said barrier region is set higher than a concentration rate of said semiconductor base.

14. An image sensor according to claim 11, wherein said barrier region is provided in contact with said charge transfer unit.

15. An image sensor according to claim 11, wherein at the time of no charge transportation, said potential barrier in said barrier region is set lower than a potential barrier between adjoining charge accumulating units according to the view points of the polarity of said signal charges.

16. A method of fabricating a back-illuminated image sensor having a barrier region, comprising the steps of:
forming an epitaxial layer of a first conductive type on a first-plane side of a substrate;
introducing impurities of said first conductive type into said epitaxial layer from said first-plane side to form a barrier region;
introducing impurities of a second conductive type different from said first conductive type into said epitaxial layer so as to form a charge transfer unit in said first-plane side at a region located shallower than said barrier region as seen from said first-plane side;
removing at least a part of said substrate to thin a second-plane side opposite of said first-plane side; and
introducing impurities of said second conductive type from said second-plane side so as to form charge accumulating units in pixel-by-pixel arrangement.

17. A method of fabricating a back-illuminated image sensor having a barrier region, comprising the steps of:
forming an epitaxial layer of a first conductive type on a first-plane side of a substrate;
introducing impurities of said first conductive type into said epitaxial layer from said first-plane side to form a barrier region;
introducing impurities of said first conductive type into the first-plane side of said first epitaxial layer at a region located shallower than said charge accumulating units as seen from said first-plane side, thereby forming a barrier region;
forming a second epitaxial layer of said first conductive type on the first-plane side of said first epitaxial layer;
introducing impurities of said second conductive type into the first-plane side of said second epitaxial layer to form a charge transfer unit; and
removing at least a part of said substrate to thin a second-plane side opposite of said first-plane side.

18. A method of fabricating a back-illuminated image sensor having a barrier region, comprising the steps of:
forming a first epitaxial layer of a first conductive type on a first-plane side of a substrate;
introducing impurities of a second conductive type different from said first conductive type into said first epitaxial layer from the first-plane side so as to form charge accumulating units in pixel-by-pixel arrangement;
forming a second epitaxial layer of said first conductive type on the first-plane side of said first epitaxial layer;
introducing impurities of said first conductive type into the first-plane side of said second epitaxial layer so as to form a barrier region;
introducing impurities of said second conductive type into the first-plane side of said second epitaxial layer at a region located shallower than said charge accumulating units as seen from the first-plane side, thereby forming a charge transfer unit; and
removing at least a part of said substrate to thin a second-plane side opposite of said first-plane side.

19. A back-illuminated image sensor comprising:
a semiconductor base of a first conductive type;
a plurality of charge accumulating units of a second conductive type different from said first conductive type, formed on a second-plane side which is the backside of a first plane of said semiconductor base, said charge accumulating units which accumulate, on a pixel-to-pixel basis, signal charges generated by an energy ray incident from the second-plane side;
a charge transfer channel formed on the first-plane side of said semiconductor base facing said charge accumulating units, the charge transfer channel which transfers said signal charges; and
transfer electrodes which apply a transfer voltage to said charge transfer channel, and wherein
said transfer electrodes are provided in a charge transfer direction of said charge transfer channel, in proportion of substantially two or less said transfer electrodes per one said charge accumulating unit.

20. An image sensor according to claim 19, wherein said transfer electrodes are periodically provided in a charge transfer direction of said charge transfer channel, in proportion of substantially two said electrodes per one said charge accumulating unit.

21. An image sensor according to claim 19, comprising:
a split transport unit which transports signal charges from said charge accumulating units to said charge transfer channel, said transporting being performed at phase intervals of said transfer electrodes, and the split transport unit which transports one screenful of signal charges at a plurality of times while shifting the phases of positions where signal charges are to be transported; and
a split transfer unit which drives said transfer electrodes in multi-phase, each time said split transport unit transports signal charges to said charge transfer channel, and the split transfer unit which reads out one screenful of signal charges at a plurality of times.

22. An image sensor according to claim 20, wherein said charge transfer channel has variations in impurity concentration in every interval of said transfer electrodes, and said transfer electrodes are driven in two phases to progressively transfer signal charges.

23. An alignment device comprising:
an image sensor according to claim 1;
a position detecting unit which is electrically connected to said image sensor and detects positional information of the object according to the image sensed of an object or a mark formed on the object by using said image sensor; and
a position controlling unit which is electrically connected to said position detecting unit and performs a positioning operation of said object according to said positional information.

24. An alignment device comprising:
an image sensor according to claim 5;
a position detecting unit which is electrically connected to said image sensor and detects positional information of the object according to the image sensed of an object or a mark formed on the object by using said image sensor; and
a position controlling unit which is electrically connected to said positioning detecting unit and performs a positioning operation of said object according to said positional information.

25. An alignment device comprising:
an image sensor according to claim 6;
a position detecting unit which is electrically connected to said mage sensor and detects positional information of the object according to the image sensed of an object or a mark formed on the object by using said image sensor; and
a position controlling unit which is electrically connected to said position detecting unit and performs a positioning operation of said object according to said positional information.

26. An alignment device comprising:
an image sensor according to claim 7;
a position detecting unit which is electrically connected to said image sensor and detects positional information of the object according to the image sensed of an object or a mark formed on the object by using said image sensor; and
a position controlling unit which is electrically connected to said position detecting unit and performs a positioning operation of said object according to said positional information.

27. An alignment device comprising:
an image sensor according to claim 8;
a position detecting unit which is electrically connected to said image sensor and detects positional information of the object according to the image sensed of an object or a mark formed on the object by using said image sensor; and
a position controlling unit which is electrically connected to said position detecting unit and performs a positioning operation of said object according to said positional information.

28. An exposure apparatus comprising:
an image sensor according to claim 1;
a position detecting unit which is electrically connected to said image sensor and detects positional information of the object according to the image sensed of an object or a mark formed on the object by using said image sensor; and
a position controlling unit which is electrically connected to said position detecting unit and performs a positioning operation of said object according to said positional information; and
an exposure unit which exposes said substrate positioned by said position controlling unit with a predetermined pattern.

29. An exposure apparatus comprising:
an image sensor according to claim 5;
a position detecting unit which is electrically connected to said image sensor and detects positional information of the object according to the image sensed of an object or a mark formed on the object by using said image sensor; and
a position controlling unit which is electrically connected to said position detecting unit and performs a positioning operation of said object according to said positional information; and
an exposure unit which exposes said substrate positioned by said position controlling unit with a predetermined pattern.

30. An exposure apparatus comprising:
an image sensor according to claim 6;
a position detecting unit which is electrically connected to said image sensor and detects positional information of the object according to the image sensed of an object or a mark formed on the object by using said image sensor; and
a position controlling unit which is electrically connected to said position detecting unit and performs a positioning operation of said object according to said positional information; and
an exposure unit which exposes said substrate positioned by said position controlling unit with a predetermined pattern.

31. An exposure apparatus comprising:
an image sensor according to claim 7;
a position detecting unit which is electrically connected to said image sensor and detects positional information of the object according to the image sensed of an object or a mark formed on the object by using said image sensor; and
a position controlling unit which performs a positioning operation of said object according to said positional information; and
an exposure unit which exposes said substrate positioned by said position controlling unit with a predetermined pattern.

32. An exposure apparatus comprising:
an image sensor according to claim 8;
a position detecting unit which is electrically connected to said image sensor and detects positional information of the object according to the image sensed of an object or a mark formed on the object by using said image sensor; and
a position controlling unit which performs a positioning operation of said object according to said positional information; and
an exposure unit which exposes said substrate positioned by said position controlling unit with a predetermined pattern.

33. An aberration measuring device comprising:
an image sensor according to claim 1;
an aberration measuring optical system which emits a pencil of light for aberration measurement to an optical system to be measured;
a condenser lens which condenses said pencil of light passing through said optical system to be measured, onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

34. An aberration measuring device comprising:
an image sensor according to claim 5;
an aberration measuring optical system which emits a pencil of light for aberration measurement to an optical system to be measured;
a condenser lens which condenses said pencil of light to pass through said optical system to be measured, onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

35. An aberration measuring device comprising:
an image sensor according to claim 6;
an aberration measuring optical system which emits a pencil of light for aberration measurement to an optical system to be measured;
a condenser lens which condenses said pencil of light to pass through said optical system to be measured, onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

36. An aberration measuring device comprising:
an image sensor according to claim 7;
an aberration measuring optical system which emits a pencil of light for aberration measurement to an optical system to be measured;
a condenser lens which condenses said pencil of light to pass through said optical system to be measured, onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

37. An aberration measuring device comprising:
an image sensor according to claim 8;
an aberration measuring optical system which emits a pencil of light for aberration measurement to an optical system to be measured;
a condenser lens which condenses said pencil of light to pass through said optical system to be measured, onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

38. An exposure apparatus comprising:
an image sensor according to claim 1;
an exposure unit which projects an exposure pattern onto a substrate to be exposed, through a projection optical system;
an aberration measuring optical system which emits a pencil of light for aberration measurement to said projection optical system;
a condenser lens which condenses said pencil of light to pass through said projection optical system onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

39. An exposure apparatus comprising:
an image sensor according to claim 5;
an exposure unit which projects an exposure pattern onto a substrate to be exposed, through a projection optical system;
an aberration measuring optical system which emits a pencil of light for aberration measurement to said projection optical system;
a condenser lens which condenses said pencil of light to pass through said projection optical system onto an imaging plane of said image sensor;
a position detecting unit which is electrically connected to said image sensor and detects positional information of said pencil of light condensed on said imaging plane; and
an operation unit which is connected to said position detecting unit and determines an aberration of said optical system to be measured, according to a detection result from said position detecting unit.

40. An exposure apparatus comprising:
an image sensor according to claim 6;
an exposure unit which projects an exposure pattern onto a substrate to be exposed, through a projection optical system;
an aberration measuring optical system which emits a pencil of light for aberration measurement to said projection optical system;
a condenser lens which condenses said pencil of light to pass through said projection optical system onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

41. An exposure apparatus comprising:
an exposure unit which projects an exposure pattern onto a substrate to be exposed, through a projection optical system;
an aberration measuring optical system which emits a pencil of light for aberration measurement to said projection optical system;
a condenser lens which condenses said pencil of light to pass through said projection optical system onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

42. An exposure apparatus comprising:
an image sensor according to claim 8;
an exposure unit which projects an exposure pattern onto a substrate to be exposed, through a projection optical system;
an aberration measuring optical system which emits a pencil of light for aberration measurement to said projection optical system;
a condenser lens which condenses said pencil of light to pass through said projection optical system onto an imaging plane of said image sensor;
a position detecting unit which is electrically connected to said image sensor and detects positional information of said pencil of light condensed on said imaging plane; and
an operation unit which is electrically connected to said position detecting unit and determines an aberration of said optical system to be measured, according to a detection result from said position detecting unit.

43. A measuring device comprising:
an image sensor according to claim 11; and
a measuring unit which is electrically connected to said image sensor and performs at least one of aberration measurement and position measurement of a subject, according to an image of the subject sensed by said image sensor.

44. A measuring device comprising:
an image sensor according to claim 19; and
a measuring unit which is electrically connected to said image sensor and performs at least one of aberration measurement and position measurement of a subject, according to an image of said subject sensed by said image sensor.

45. An exposure apparatus comprising:
an image sensor according to claim 11;
an exposure unit which projects an exposure pattern onto an object to be exposed;
a measuring unit which is electrically connected to said image sensor and performs at least one of aberration measurement and position measurement of a subject, according to an image of said subject sensed by said image sensor; and
a control unit which is electrically connected to said measuring unit and performs at least one of aberration correction on said exposure unit and positional control of an exposure position, according to a measurement output from said measuring unit.

46. An exposure apparatus comprising:
an image sensor according to claim 19;
an exposure unit which projects an exposure pattern onto an object to be exposed;
a measuring unit which is electrically connected to said image sensor and performs at least one of aberration measurement and position measurement of a subject, according to an image of said subject sensed by said image sensor; and
a control unit which is electrically connected to said measuring unit and performs at least one of aberration correction on said exposure unit and positional control of an exposure position, according to a measurement output from said measuring unit.

47. A method of fabricating a device comprising:
a mark forming step of forming a first alignment mark on a first-plane side of a substrate;
a base forming step of forming a base portion of a device on the first-plane side of said substrate;
a first-plane side processing step of forming a first structure on the first-plane side of said base portion by using, as a reference, one of a projection and a depression which appears on the first-plane side of said base portion in the process of forming said base portion;
a removing step of removing said substrate from a second-plane side of said base portion opposite to said first-plane side; and
a second-plane side processing step of forming a second structure on the second-plane side of said base portion by using, as a reference, a second alignment mark which appears on the second-plane side of said base portion in the process of removing said substrate, said second structure being different from said first structure.

48. A method of fabricating a device comprising:
a base forming step of forming a base portion of a device on a first-plane side of a substrate;
a to-be removed region forming step of forming, in said base portion, a to-be-removed region which reaches said substrate and is selectively removable;
a mark forming step of forming a first alignment mark on the first-plane side in said to-be-removed region;
a first-plane side processing step of forming a first structure on the first-plane side of said base portion by using said first alignment mark as a reference;
a layer forming step of forming a layer to cover at least said first alignment mark;
a removing step of removing said substrate and said to-be-removed region from a second-plane side of said base portion which is opposite of said first-plane side; and
a second-plane side processing step of forming a second structure on the second-plane side of said base portion by using, as a reference, a second alignment mark which appears on the second-plane side in the process of removing said substrate, said second structure being different from said first structure.

49. A method of fabricating a device comprising:
a mark forming step of forming a first alignment mark on a first-plane side of a substrate;
a base forming step of forming a base portion of a device on the first-plane side of said substrate;
a step of forming a first structure on the first-plane side of said base portion by using, as a reference, one of a projection and a depression which appears on the first-plane side of said base portion in the process of forming said base portion;
a processing step of forming a predetermined structure on the first-plane side of said base portion by using, as a reference, a second alignment mark which appears on the second-plane side of said base portion in the process of removing said substrate, said second structure being different from said first structure.

50. A method of fabricating a device comprising:
a mark forming step of forming a first alignment mark being one of a projection and a depression on a first-plane side of a substrate;
a base forming step of forming a base portion of a device on the first-plane side of said substrate;
a removing step of removing said substrate from a second-plane side of said base portion which is opposite to the first-plane side, so that a second alignment mark appears on the second-plane side of said base portion; and
a processing step of forming a predetermined structure on the second-plane side of said base portion by using said second alignment mark as a reference.

51. A method of fabricating a device comprising:
a base forming step of forming a base portion of a device on a first-plane side of a substrate, where a first alignment mark is formed;
a to-be-removed region forming step of forming a to-be-removed region in said base portion, said to-be-removed region reaching said substrate and being selectively removable;
a layer forming step of forming a layer to cover at least said first alignment mark;
a removing step of removing said substrate and said to-be-removed region from a second-plane side of said base portion which is opposite to the first-plane side, so that a second alignment mark appears on the second-plane side of said base portion; and
a processing step of forming a predetermined structure on the second-plane side of said base portion by using said second alignment mark as a reference.

52. A method of fabricating a device comprising:
a base forming step of forming a base portion of a device on a first-plane side of a substrate;
a to-be-opened region forming step of forming a to-be-opened region in a to-be-opened area of said base portion during or after the process of forming said base portion, said to-be-opened region reaching said substrate and being selectively removable; and
a removing step of removing said substrate and said to-be-opened region from a second-plane side of said base portion, which is opposite to the first-plane side, so that an opening hole (a trace of said removed to-be-opened region) appears on the second-plane side of said base portion.

53. A method for fabricating a device according to any one of claims 47, 49, 50, and 51, wherein said substrate includes antimony (Sb).

54. A method for fabricating a device according to one of claims 48 and 51, wherein in said to-be-removed region is made of material including antimony (Sb) in said to-be-removed region forming step.
